(19) United States
(12) Patent Application Publication
(10) Pub. No.: US 2026/0123140 A1
(43) Pub. Date: Apr. 30, 2026

(54) DISPLAY DEVICE

(71) Applicant: LG Display Co., Ltd., Seoul (KR)

(72) Inventors: YuRa JEONG, Seoul (KR); HaeYoon JUNG, Seoul (KR); Aesun KIM, Paju-si (KR); MyungSub LIM, Seoul (KR); Injun LEE, Gimpo-si (KR)

(73) Assignee: LG Display Co., Ltd., Seoul (KR)

(21) Appl. No.: 19/310,433

(22) Filed: Aug. 26, 2025

(30) Foreign Application Priority Data
Oct. 24, 2024 (KR) 10-2024-0146878

(51) Int. Cl. H10H 29/49

(52) U.S. Cl. CPC H10H 29/49

(57) ABSTRACT

Disclosed are a display device. The display device includes a lower substrate having an active area, a first non-active area on both sides of the active area along a first direction, and a second non-active area on one side of the active area along a second direction different from the first direction. A plurality of plate patterns are provided in the active area, the first non-active area, and the second non-active area, and a plurality of line patterns are disposed between adjacent plate patterns in each of these areas. The plate patterns located in the second non-active area have different sizes, with plate patterns closer to the active area formed smaller than those farther away. By varying plate pattern size and arranging line patterns accordingly, stretching stress applied to the non-active area may be dispersed, thereby reducing the likelihood of cracking and enhancing mechanical reliability of the device.

### CROSS-REFERENCE TO RELATED APPLICATIONS

This application claims the priority and benefits of Korean Patent Application No. 10-2024-0146878 filed on Oct. 24, 2024, in the Korean Intellectual Property Office, the entire contents of which are hereby expressly incorporated herein for all purposes.

### BACKGROUND

### Technical Field

The present disclosure relates to a display device, and more particularly to a stretchable display device which may be stretched.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, recently, a display device which is manufactured by forming a display unit and a wiring line on a flexible substrate such as plastic which is a flexible material so as to be stretchable in a specific direction and changed in various forms is getting attention as a next generation display device.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### BRIEF SUMMARY

In the related art, a non-active area of a display device is easily subject to excessive stretching and a pattern layer of the display device is readily damaged due to a cracking. Accordingly, the present disclosure provides a display device that minimizes a stretching stress.

To be specific, the disclosure addresses limitations of conventional flexible and stretchable displays, namely excessive stretching in non-active areas and cracking in pattern layers. The disclosure emphasizes that plate patterns in the second non-active area are formed with gradually decreasing sizes toward the active area, which disperses stress during stretching and suppresses crack formation.

Another aspect is the use of non-uniform line pattern geometries, where line patterns are configured with different length ratios such as varying wave or zigzag shapes. This arrangement ensures that some lines stretch more than others, effectively preventing over-extension of the non-active area and protecting the integrity of the pattern layer. In addition, link lines are positioned on line patterns within the non-active region, enabling stable electrical signal transmission while accommodating mechanical deformation.

The arrangement of plate patterns and line patterns on a flexible substrate provides structural configurations that contribute to both flexibility and durability. Features such as variation in plate sizes, adjustment of line pattern geometries, and placement of link lines may be implemented individually or in combination to influence the distribution of mechanical stress and to reduce the likelihood of cracking. Through these design approaches, a display device can achieve improved stretchability and mechanical reliability while maintaining electrical performance.

For example, various embodiments of the present disclosure provide a display device which suppresses the excessive stretching of the non-active area.

various embodiments of the present disclosure provide a display device which suppresses a damage or a crack of a pattern layer.

Technical benefits of the present disclosure are not limited to the above-mentioned benefits, and other benefits, which are not mentioned above, can be clearly understood by those skilled in the art from the following descriptions.

In order to achieve the above-described benefits, according to an aspect of the present disclosure, a display device includes a lower substrate including an active area, a first non-active area on both sides of the active area along a first direction, and a second non-active area on one side of the active area along a second direction which is different from the first direction, a plurality of plate patterns in the active area, the first non-active area, and the second non-active area, and a plurality of line patterns between the plurality of plate patterns in the active area, the first non-active area, and the second non-active area and the plurality of plate patterns disposed in the second non-active area has a different size.

In order to achieve the above-described objects, according to an aspect of the present disclosure, a display device may include a lower substrate including an active area, a first non-active area on both sides of the active area along a first direction, and a second non-active area on one side of the active area along a second direction which is different from the first direction, a plurality of plate patterns in the active area, the first non-active area, and the second non-active area, a plurality of line patterns between the plurality of plate patterns in the active area, the first non-active area, and the second non-active area, and a plurality of link lines on the plurality of line patterns in the second non-active area.

Other detailed matters of the exemplary embodiments are included in the detailed description and the drawings.

In the display device according to the exemplary embodiments of the present disclosure, in a non-active area disposed on one side of the active area, a size (or an area) of a plate pattern bonded to the flexible film is gradually reduced toward the active area from the flexible film. Accordingly, when the display device is stretched, a stretching stress of a line pattern which connects adjacent plate patterns in the non-active area and a link line disposed on the line pattern may be effectively dispersed. Therefore, the damage or crack of the pattern layer included in the display device may be suppressed.

Further, in the case of the display device according to the exemplary embodiments of the present disclosure, a length ratio of a line pattern connected to the plate pattern which is bonded to the flexible film in the non-active area may have a different value in every line pattern. Accordingly, the over-stretching of the non-active area when the display device is stretched may be suppressed and the damage or the crack of the pattern layer included in the display device may be suppressed.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view schematically illustrating a display device according to exemplary embodiments of the present disclosure;

FIG. 2 is a plan view of an active area and a first non-active area of a display device according to exemplary embodiments of the present disclosure;

FIG. 3 is an enlarged plan view of an example of an active area of a display device of FIG. 2;

FIG. 4 is a cross-sectional view illustrating an example taken along the line IV-IV′ illustrated in FIG. 3;

FIG. 5 is a plan view of an active area and first to third non-active areas of a display device according to exemplary embodiments of the present disclosure;

FIGS. 6A to 6H are enlarged plan views illustrating an example of an island area of a display device of FIG. 5;

FIGS. 7A and 7B are views for explaining an example of a third line pattern included in a display device of FIG. 5;

FIG. 8 is a graph for explaining examples of a stretching stress applied to a line pattern when a display device according to exemplary embodiments of the present disclosure is stretched;

FIGS. 9A to 9I are views for explaining examples of a stretching stress applied to a display device when a display device according to exemplary embodiments of the present disclosure is stretched;

FIG. 10 is a view for explaining an example of a link line included in a display device of FIG. 5;

FIG. 11 is an enlarged plan view illustrating an example of a part A of FIG. 10; and

FIG. 12 is a cross-sectional view illustrating an example taken along the line V-V′ of FIG. 11.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “include,” “have,” “comprise,” “contain,” “constitute,” “make up of,” “formed of,” and “consist of” used herein are generally intended to allow other components to be added unless the terms are used with the term “only”. Any references to singular may include plural unless expressly stated otherwise.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Components are interpreted to include an ordinary error range even if not expressly stated.

When described as “connected” or “coupled,” unless the terms “directly” or “immediately” are used, the connection or coupling may include indirect connections or couplings through one or more other components positioned between the two elements.

When the position relation between two parts is described using the terms such as “on”, “above”, “over”, “below”, “under”, “beside”, “beneath”, “near”, “close to,” “adjacent to”, “on a side of”, “next”, one or more parts may be positioned between the two parts unless the terms are used with the term “immediately” or “directly”.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

The word “exemplary” is used to mean serving as an example or illustration. Aspects are example aspects. “Embodiments,” “examples,” “aspects,” and the like should not be construed as preferred or advantageous over other implementations. An embodiment, an example, an exemplary embodiment, an aspect, or the like may refer to one or more embodiments, one or more examples, one or more example embodiments, one or more aspects, or the like, unless stated otherwise. Further, the term “may” encompasses all the meanings of the term “can”.

When an element or layer is disposed “on” another element or layer, another layer or another element may be interposed directly on the other element or therebetween.

When a temporal relationship is described, for example, when terms for temporal relationship of events such as “after”, “subsequently”, “next”, and “before” are used, there may also be the case in which the events are not continuous, unless “immediately” or “directly” is used.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In the specification, in adding reference numerals for elements in each drawing, it should be noted that like reference numerals already used to denote like elements in other drawings are used for elements wherever possible. In addition, the dimension scales of constituent elements shown in the drawings may be different from actual dimension scales, for convenience of description. That is, the dimension scales of constituent elements shown in the drawings should not be interpreted to be the same as those shown in the drawings.

Hereinafter, the present disclosure will be described in detail with reference to accompanying drawings.

A display device according to exemplary embodiments of the present disclosure is a display device which is capable of displaying images even in a bent or extended state and is also referred to as a stretchable display device, a flexible display device and an extendable display device. As compared with the general display devices of the related art, the display device has not only a high flexibility, but also stretchability. Therefore, the user may bend or extend a display device and a shape of a display device may be freely changed in accordance with manipulation of a user. For example, when the user pulls the display device by holding ends of the display device, the display device may be extended to the pulling direction of the user. Alternatively, when the user disposes the display device on an outer surface which is not flat, the display device may be disposed to be bent in accordance with the shape of the outer surface of the wall. Further, when a force applied by the user is removed, the display device may return to its original shape.

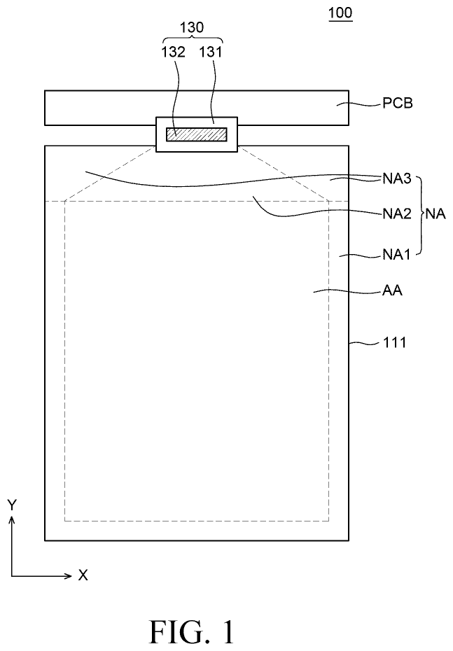

FIG. 1 is a plan view schematically illustrating a display device according to exemplary embodiments of the present disclosure.

In the meantime, for the convenience of description, in FIG. 1, among various configurations of the display device 100, only a lower substrate 111, a flexible film 130, and a printed circuit boards PCB are illustrated.

Referring to FIG. 1, the lower substrate 111 may support several components of the display device 100. The lower substrate 111 may include an active area AA in which images are displayed and a non-active area NA excluding the active area AA. For example, the non-active area NA surrounds the active area AA.

On the active area AA, a plurality of pixels each including a display element and a circuit element is disposed and on the non-active area NA, a gate driver and a power supply for driving the plurality of pixels disposed in the active area AA may be disposed. The non-active area NA is an area where an image is not displayed, and may be defined in an edge portion of the lower substrate 111 to surround a portion or the entirety of the active area AA. The non-active area NA may be an area adjacent to the active area AA. Further, the non-active area NA may be an area disposed adjacent to the active area AA and configured to surround the active area AA. However, the present disclosure is not limited thereto.

In one exemplary embodiment, the non-active area NA may include a first non-active area NA1, a second non-active area NA2, and a third non-active area NA3.

The first non-active area NA1 may be located on a left side, a right side, and a lower side of the active area AA. For example, the first non-active area NA1 may be disposed on both sides (for example, a left side and a right side) of the active area AA along a first direction X and on one side (for example, a lower side) along an opposite direction of a second direction Y. The gate driver and the power supply may be disposed on the first non-active area NA1.

The second non-active area NA2 may be an area which corresponds to a part of the non-active area NA on an upper side of the active area AA. For example, the second non-active area NA2 may be disposed on one side (for example, an upper side) of the active area AA along the second direction Y. In the second non-active area NA2, a plurality of pads connected to the flexible film 130 and a plurality of link lines which transmits a signal to the active area AA from the plurality of pads may be disposed. The second non-active area NA2 is an area between a plurality of pads from an upper side of the active area AA and may have a shape widened toward the active area AA from the plurality of pads. For example, the second non-active area NA2 may radially expand with respect to the plurality of pads.

The third non-active area NA3 may be a remaining area of the non-active area NA disposed on the upper side of the active area AA excluding the second non-active area NA2. For example, the third non-active area NA3 may be disposed on both sides of the second non-active area NA2. For example, the third non-active area NA3 may be disposed on both sides (for example, a left side and a right side) of the second non-active area NA2 along the first direction X.

A boundary area between the active area AA and the non-active area NA may be bent so that the non-active area NA may be located below the display area. In this case, when the user looks at the display device from the front, there may be little or no non-active area NA visible to the user.

The flexible film 130 is a film in which various components are disposed on a base film 131 having a flexibility and may supply signals to the plurality of pixels PX of the active area AA. The flexible film 130 may be bonded to the plurality of pads disposed in the second non-active area NA2 and supplies various signals to each of the plurality of pixels of the active area AA through the pad and the plurality of link lines. The flexible film 130 includes a base film 131 and a driving IC 132. Further, various components may be disposed on the flexible film 130.

The base film 131 may support the driving IC 132 of the flexible film 130. The base film 131 may be formed of an insulating material, and for example, may be formed of an insulating material having a flexibility. For example, the base film may include a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene(PS). However, the present disclosure is not limited thereto.

The driving IC 132 processes data for displaying images and a driving signal for processing the image. In FIG. 1, even though it is illustrated that the driving IC 132 is mounted by the chip on film (COF) 130 technique, it is not limited thereto and the driving IC 132 may be mounted by a technique such as chip on glass (COG) or tape carrier package (TCP).

The printed circuit board PCB may be connected to the plurality of flexible films 130. A controller, such as an IC chip or a circuit unit, may be mounted on the printed circuit board PCB. Further, on the printed circuit board PCB, a memory or a processor may also be mounted. The printed circuit board PCB may generate a signal for driving a pixel.

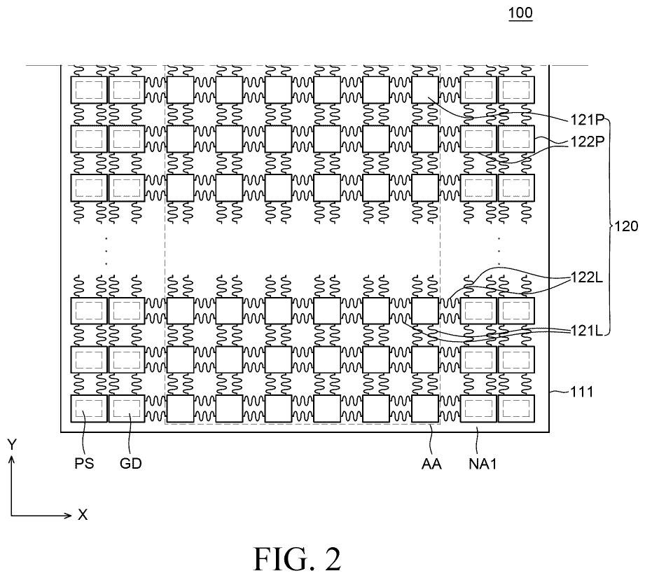

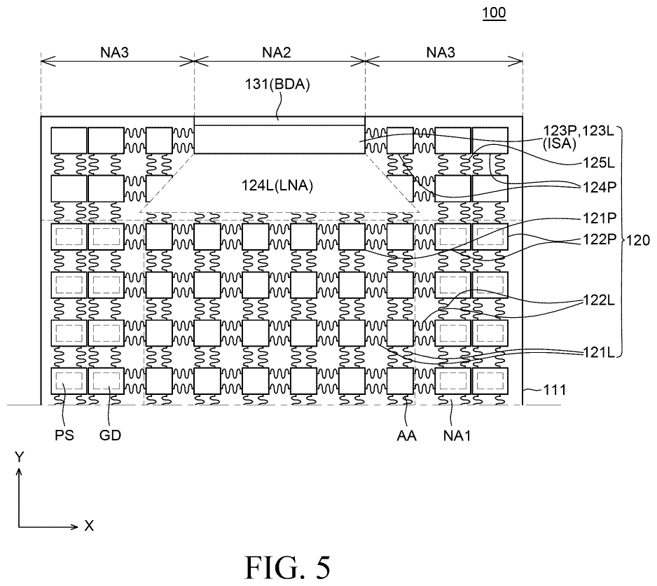

Hereinafter, the active area AA and the first non-active area NA1 of the display device 100 will be described in more detail with reference to FIGS. 2 to 4. The second non-active area NA2 and the third non-active area NA3 of the display device 100 will be described in more detail with reference to FIGS. 5 to 12.

FIG. 2 is a plan view of an active area and a first non-active area of a display device according to exemplary embodiments of the present disclosure.

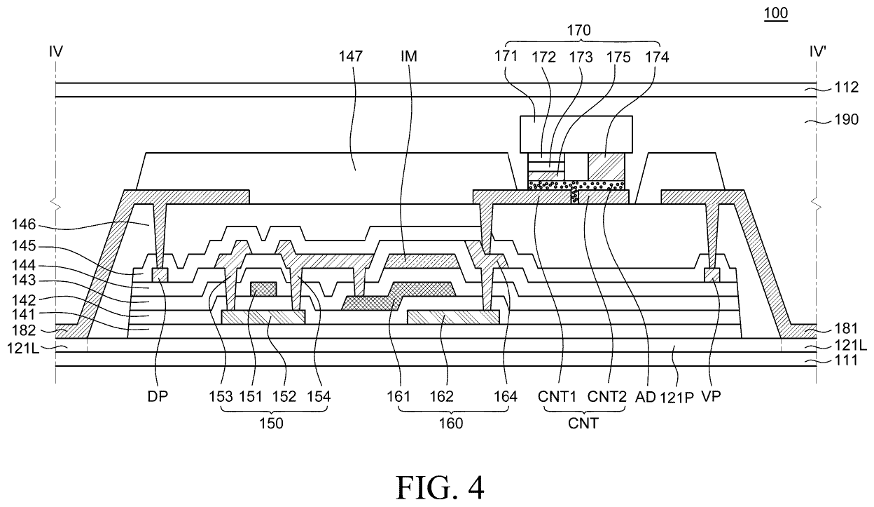

Referring to FIGS. 1 and 2, a display device 100 according to exemplary embodiments of the present disclosure may include a lower substrate 111, a pattern layer 120, a plurality of pixels PX, a gate driver GD, a data driver, and a power supply PS. In one exemplary embodiment, the display device 100 may further include an upper substrate (for example, an upper substrate 112 of FIG. 4).

The lower substrate 111 supports the pattern layer 120 on which the pixel PX, the gate driver GD, and the power supply PS are formed and the upper substrate 112 is disposed on the lower substrate 111 and may cover various components of the display device 100. In one exemplary embodiment, the lower substrate 111 and the upper substrate 112 are flexible substrates and may be configured by an insulating material which is bendable or stretchable. For example, the lower substrate 111 and the upper substrate 112 may include a flexible polymer film. For example, the flexible polymer film may be made of any one of polyimide (PI), polyethylene terephthalate (PET), acrylonitrile-butadiene-styrene copolymer(ABS), polymethyl methacrylate (PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene(PS). However, the present disclosure is not limited thereto.

Moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a timing when an object to be stretched is broken or cracked.

The pattern layer 120 may be disposed on the lower substrate 111. In one exemplary embodiment, the pattern layer 120 may include a plurality of first plate patterns 121P and a plurality of first line patterns 121L disposed in the active area AA and a plurality of second plate patterns 122P and a plurality of second line patterns 122L disposed in the first non-active area NA1. For example, the plurality of first plate patterns 121P and the plurality of second plate patterns 122P may be formed as separate islands. The plurality of first line patterns 121L connects first plate patterns 121P which are adjacent to each other and the plurality of second line patterns 122L may connects a first plate pattern 121P and a second plate pattern 122P which are adjacent to each other or a plurality of second plate patterns 122P which is adjacent to each other.

On the plurality of first plate patterns 121P, a plurality of pixels PX is formed and on the plurality of second plate patterns 122P, a gate driver GD and a power supply PS may be formed.

In the meantime, even though in FIG. 1, it is illustrated that the plurality of first plate patterns 121P and the plurality of second plate patterns 122P have a quadrangular shape, it is not limited thereto.

The plurality of first line patterns 121L and the plurality of second line patterns 122L have a wavy shape (for example, a sine wave shape), but are not limited thereto. For example, the plurality of first line patterns 121L and the plurality of second line patterns 122L may extend in a zigzag pattern or may be formed with various shapes such as a shape extended by connecting a plurality of rhombus-shaped substrates at vertexes or a shape in which semicircular or quadrant shaped substrates are connected to each other.

In one exemplary embodiment, the plurality of first plate patterns 121P, the plurality of first line patterns 121L, the plurality of second plate patterns 122P, and the plurality of second line patterns 122L of the pattern layer 120 may be rigid patterns. For example, the plurality of first plate patterns 121P, the plurality of first line patterns 121L, the plurality of second plate patterns 122P, and the plurality of second line patterns 122L may be more rigid than the lower substrate 111 and the upper substrate 112. Accordingly, moduli of elasticity and hardness of the plurality of first plate patterns 121P, the plurality of first line patterns 121L, the plurality of second plate patterns 122P, and the plurality of second line patterns 122L may be higher than a modulus of elasticity and the hardness of the lower substrate 111. For example, moduli of elasticity of the plurality of first plate patterns 121P, the plurality of first line patterns 121L, the plurality of second plate patterns 122P, and the plurality of second line patterns 122L may be 1000 times higher than the moduli of elasticity of the lower substrate 111 and the upper substrate 112, but it is not limited thereto.

The plurality of first plate patterns 121P, the plurality of first line patterns 121L, the plurality of second plate patterns 122P, and the plurality of second line patterns 122L may be formed of a plastic material having a lower flexibility than the lower substrate 111 and the upper substrate 112.

The gate driver GD may supply a gate signal to the plurality of pixels PX disposed in the active area AA. The gate driver GD includes a plurality of stages formed on the plurality of second plate patterns 122P and each stage of the gate driver GD may be electrically connected to each other by means of the plurality of gate connection lines. Accordingly, a gate signal output from any one of stages may be transmitted to the other stage. Each stage may sequentially supply the gate signal to the plurality of pixels PX connected to each stage.

The power supply PS is electrically connected to the gate driver GD and the plurality of pixels PX to supply a driving voltage.

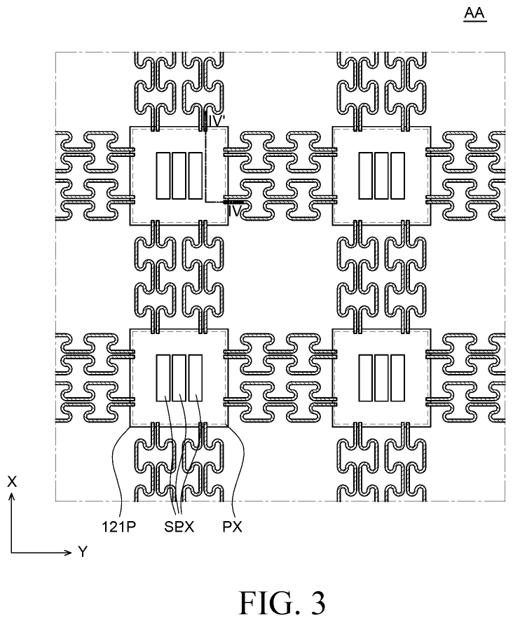

FIG. 3 is an enlarged plan view of an example of an active area of a display device of FIG. 2.

FIG. 4 is a cross-sectional view illustrating an example taken along the line IV-IV′ illustrated in FIG. 3.

Referring to FIGS. 1 to 3, a plurality of first plate patterns 121P may be disposed on the active area AA of the lower substrate 111. The plurality of first plate patterns 121P is spaced apart from each other to be disposed on the lower substrate 111. For example, the plurality of first plate patterns 121P may be disposed on the lower substrate 111 in a matrix, but is not limited thereto.

A pixel PX including the plurality of sub pixels SPX may be disposed in the first plate pattern 121P. Each of the plurality of sub pixels SPX may include an LED 170 (or a light emitting element) which is a display element and a circuit element for driving the LED 170, for example, at least one transistor. However, this is just illustrative and in the sub pixel SPX, the display element is not limited to an LED, and may also be changed to an organic light emitting diode.

The plurality of sub pixels SPX may include a red sub pixel, a green sub pixel, and a blue sub pixel, but is not limited thereto and colors of the plurality of sub pixels SPX may be deformed to various colors as needed.

For example, the plurality of subpixels may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

The plurality of sub pixels SPX may be connected to a plurality of connection lines 181 and 182. For example, the plurality of sub pixels SPX may be electrically connected to a first connection line 181 extending in the first direction X and a second connection line 182 extending in the second direction Y.

Hereinafter, a cross-sectional structure of the display device 100 according to an exemplary embodiment of the present disclosure in the active area AA will be described in more detail with reference to FIG. 4.

Referring to FIG. 4, a plurality of first plate patterns 121P and a plurality of first line patterns 121L which connects adjacent first plate patterns 121P may be disposed on the active area AA of the lower substrate 111.

A plurality of inorganic insulating layers may be disposed on the plurality of first plate patterns 121P. For example, the plurality of inorganic insulating layers may include a buffer layer 141, a gate insulating layer 142, a first interlayer insulating layer 143, a second interlayer insulating layer 144, and a passivation layer 145, but is not limited thereto.

The buffer layer 141 is disposed on the plurality of first plate patterns 121P and may include an insulating material. For example, the buffer layer 141 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. However, the buffer layer 141 may be excluded in accordance with the structure or properties of the display device.

In one exemplary embodiment, the buffer layer 141 is formed only in an area which overlaps the plurality of first plate patterns 121P and the plurality of second plate patterns 122P, but is not formed in an area between the plurality of first plate patterns 121P and the plurality of second plate patterns 122P.

A switching transistor 150 and a driving transistor 160 may be disposed on the buffer layer 141.

First, a switching active layer 152 of the switching transistor 150 and a driving active layer 162 of the driving transistor 160 may be disposed on the buffer layer 141.

Active layers of the switching active layer 152 of the switching transistor 150 and the driving active layer 162 of the driving transistor 160 may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The gate insulating layer 142 may be disposed on the switching active layer 152 of the switching transistor 150 and the driving active layer 162 of the driving transistor 160. The gate insulating layer 142 may include an insulating material. The gate insulating layer 142 may be formed as a single layer made of an inorganic material or a multilayer made of different inorganic materials. For example, the gate insulating layer 142 may be formed as a single layer of any one of a silicon oxide (SiOx) film, a silicon nitride (SiNx) film, and a silicon oxynitride (SiON) film, or a multilayer thereof. For example, the gate insulating layer 142 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

A switching gate electrode 151 of the switching transistor 150 and a driving gate electrode 161 of the driving transistor 160 which include a metal material and are spaced apart from each other may be disposed on the gate insulating layer 142. The switching gate electrode 151 of the switching transistor 150 and the driving gate electrode 161 of the driving transistor 160 may be formed as a single layer or multilayer made of any one of molybdenum (Mo), aluminum (Al), chromium (Cr), gold (Au), titanium (Ti), nickel (Ni), neodymium (Nd), and copper (Cu), or alloys thereof, but is not limited thereto.

The first interlayer insulating layer 143 may be disposed on the switching gate electrode 151 and the driving gate electrode 161. The first interlayer insulating layer 143 includes an insulating material and may insulate the driving gate electrode 161 from an intermediate metal layer IM. The first interlayer insulating layer 143 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The intermediate metal layer IM may be disposed on the first interlayer insulating layer 143. The intermediate metal layer IM includes various metal material and overlaps the driving gate electrode of the driving transistor 160 to form a storage capacitor. The metal material may include any one of molybdenum (Mo), aluminum (Al), chromium (Cr), gold (Au), titanium (Ti), nickel (Ni), neodymium (Nd), and copper (Cu), or alloys thereof, but is not limited thereto.

The second interlayer insulating layer 144 may be disposed on the intermediate metal layer IM. The second interlayer insulating layer 144 includes an insulating material and may insulate the switching gate electrode 151 from the switching source electrode 153 and the switching drain electrode 154 of the switching transistor 150. Further, the second interlayer insulating layer 144 may insulate the intermediate metal layer IM from the driving source electrode and the driving drain electrode 164 of the driving transistor 160. The second interlayer insulating layer 144 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

On the second interlayer insulating layer 144, the switching source electrode 153 and the switching drain electrode 154 of the switching transistor 150 each including a metal material are spaced apart from each other and the driving source electrode and the driving drain electrode 164 of the driving transistor 160 may be spaced apart from each other. The switching source electrode 153 and the switching drain electrode 154 may be formed as a single layer or multilayer made of any one of molybdenum (Mo), aluminum (Al), chromium (Cr), gold (Au), titanium (Ti), nickel (Ni), neodymium (Nd), and copper (Cu), or alloys thereof, but is not limited thereto. The switching source electrode 153 and the switching drain electrode 154 may be electrically connected to the switching active layer 152 through a contact hole. The driving source electrode and the driving drain electrode 164 may be electrically connected to the driving active layer 162 through a contact hole. Further, the switching drain electrode 154 of the switching transistor 150 may be electrically connected to the driving gate electrode 161 of the driving transistor 160 through a contact hole.

Further, a gate pad, a data pad DP, and a voltage pad VP may be disposed on the second interlayer insulating layer 144.

The gate pad is connected to the first connection line 181 through a contact hole to transmit a gate voltage to the plurality of sub pixels SPX.

The data pad DP is connected to the second connection line 182 through a contact hole to transmit a data voltage to the plurality of sub pixels SPX.

The voltage pad VP is connected to the first connection line 181 through a contact hole to transmit a power voltage to the plurality of sub pixels SPX.

The passivation layer 145 may be disposed on the switching transistor 150, the driving transistor 160, the gate pad GP, the data pad DP, and the voltage pad VP. The passivation layer 145 includes an insulating material and protects various components disposed below the passivation layer 145 from moisture and oxygen. The passivation layer 145 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

In the meantime, the gate insulating layer 142, the first interlayer insulating layer 143, the second interlayer insulating layer 144, and the passivation layer 145 are patterned to be the same as the buffer layer 141 to be formed only in an area overlapping the plurality of first plate patterns 121P. The gate insulating layer 142, the first interlayer insulating layer 143, the second interlayer insulating layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 may also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of first plate patterns 121P. However, the gate insulating layer 142, the first interlayer insulating layer 143, the second interlayer insulating layer 144, and the passivation layer 145 are patterned to have a shape of the plurality of first plate patterns 121P to be formed only above the plurality of first plate patterns 121P.

The planarization layer 146 may be disposed on the passivation layer 145. The planarization layer 146 may planarize upper portions of the switching transistor 150 and the driving transistor 160. The planarization layer 146 may be configured by a single layer or a plurality of layers and may be formed of an organic material. For example, the planarization layer 146 may be made of an organic insulating material, such as acrylic resin, epoxy resin, polyimide, polyethylene, or silicon oxycarbon (SiOC), but not limited thereto.

Referring to FIGS. 2 to 4, the plurality of connection lines 181 and 182 may be disposed on the plurality of first line patterns 121L and the plurality of second line patterns 122L. The plurality of connection lines 181 and 182 may electrically connect the pads on the plurality of first plate patterns 121P and pads on the plurality of second plate patterns 122P. The plurality of connection lines 181 and 182 may extend onto the plurality of first plate patterns 121P so as to be electrically connected to the pad on the plurality of first plate patterns 121P. The plurality of first line patterns 121L is not disposed in an area where the plurality of connection lines 181 and 182 is not disposed, among areas between the plurality of first plate patterns 121P. Further, even though it is not illustrated in the drawing, the plurality of connection lines 181 and 182 is disposed on the plurality of second line patterns 122L to be electrically connected to a pad on the plurality of second plate patterns 122P and a pad on the plurality of first plate patterns 121P.

The plurality of connection lines 181 and 182 may include a plurality of first connection lines 181 and the plurality of second connection lines 182 which are disposed between the plurality of first plate patterns 121P and the plurality of second plate patterns 122P to connect pads on two adjacent plate patterns.

The plurality of first connection lines 181 may be disposed on a top surface of the first line pattern 121L and both ends extend above the first plate pattern 121P to be in contact with a top surface and a side surface of the planarization layer 146.

A connection pattern CNT may be disposed on the planarization layer 146. The connection pattern CNT may electrically connect the LED 170 and the driving transistor 160 and the low potential power line. For example, the connection pattern CNT may include a first connection pattern CNT1 and a second connection pattern CNT2. The first connection pattern CNT1 may electrically connect the drain electrode of the driving transistor 160 and the p-electrode 175 of the LED 170 and the second connection pattern CNT2 may electrically connect the low potential power line and the n-electrode 174 of the LED 170. In this case, the second connection pattern CNT2 extends from the connection lines 181 and 182 which transmit the low potential power voltage to be integrally formed with the connection lines 181 and 182. Therefore, when the display device 100 is driven, different voltage levels applied to the first connection pattern CNT1 and the second connection pattern CNT2 are transmitted to the n-electrode 174 and the p-electrode 175 so that the LED 170 may emit light.

A bank 147 may be formed on the connection pattern CNT, the connection lines 181 and 182, and the planarization layer 146. The bank 147 includes an insulating material and divides adjacent sub pixels SPX. The bank 147 may be disposed so as to cover at least a part of the connection pattern CNT, the connection lines 181 and 182, and the planarization layer 146.

For example, the bank 147 may include a first bank and a second bank. The first bank may be made of an opaque material (e.g., black material) to suppress the optical interference between adjacent sub-pixels. The second bank may be made of a transparent material. The first bank and the second bank may include, but is not limited to, a light-shielding material made of at least one of a color pigment, an organic black material, and carbon.

Meanwhile, the first bank and the second bank may be formed as separate configurations, but may also be formed integrally to form one bank.

The first bank and the second bank may be disposed at a boundary between the plurality of subpixels and suppress a color mixture of light beams from the plurality of subpixels.

The LED 170 may be disposed on the connection pattern CNT. The LED 170 may include an n-type layer 171, an active layer 172, a p-type layer 173, an n-electrode 174, and a p-electrode 175.

The p-type layer 173 is disposed on the connection pattern CNT and the n-type layer 171 may be disposed on the p-type layer 173.

The active layer 172 (or the emission layer) may be disposed between the n-type layer 171 and the p-type layer 173.

Further, a predetermined part of the n-type layer 171, the active layer 172, and the p-type layer 173 which are sequentially laminated is etched and the n-electrode 174 is disposed on one surface of the n-type layer 171 exposed in an etched area and the p-electrode 175 may be disposed on one surface of the p-type layer 173 which is disposed in a non-etched area. An adhesive layer AD may be disposed between the LED 170 and the connection pattern CNT. The adhesive layer AD is disposed between the n-electrode 174 and the p-electrode 175 of the LED 170 and the connection pattern CNT so that the n-electrode 174 and the p-electrode 175 may be electrically connected to the connection pattern CNT through the adhesive layer AD.

The upper substrate 112 may be disposed on the LED 170 and the lower substrate 111. The upper substrate 112 may support various components disposed below the upper substrate 112.

A filling layer 190 may be disposed between the lower substrate 111 and the upper substrate 112. The filling layer 190 may be fully filled in an empty space between the lower substrate 111 and the upper substrate 112. For example, the filling layer 190 may be configured by a curable adhesive.

FIG. 5 is a plan view of an active area and first to third non-active areas of a display device according to exemplary embodiments of the present disclosure.

Referring to FIGS. 1 to 5, as described above, a display device 100 according to exemplary embodiments of the present disclosure may include a lower substrate 111, a pattern layer 120, a plurality of pixels PX, a gate driver GD, a data driver, a power supply PS, and an upper substrate 112.

In one exemplary embodiment, the pattern layer 120 may further include a plurality of third plate patterns 123P, a plurality of third line patterns 123L, and a plurality of fourth line patterns 124L disposed in the second non-active area NA2 and a plurality of fourth plate patterns 124P and a plurality of fifth line patterns 125L disposed in the third non-active area NA3.

First, the plurality of third plate patterns 123P is disposed in an island area ISA of the second non-active area NA2 between a bonding area BDA and a link line area LNA to be connected to the plurality of pads formed on the base film 131 of the flexible film 130. For example, the third plate pattern 123P may support a plurality of connection pads which is connected to the plurality of pads formed on the bonding area BDA of the base film 131 and a plurality of link lines connected thereto. The plurality of connection pads formed on the third plate pattern 123P may be bonded to a flexible film 130 in the bonding area BDA. According to the exemplary embodiment, a width (for example, a horizontal width) of the island area ISA along a first direction X may be equal to a width (for example, a horizontal width) of the bonding area BDA along the first direction X.

A size (or an area) of the plurality of third plate patterns 123P may vary in every area. For example, the more adjacent to the active area AA, for example, the closer to the opposite direction to the second direction Y, the smaller the size (or area) of the plurality of third plate patterns 123P.

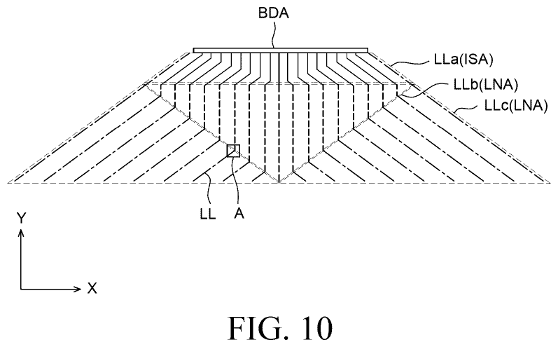

The plurality of link lines extends from the third plate patterns 123P to the link line area LNA to transmit a signal which is supplied from the plurality of pads on the flexible film 130 to the active area AA. For example, one end of the plurality of link lines is connected to the plurality of pads formed on the bonding area BDA of the base film 131 and the other ends of the plurality of link lines may be connected to the plurality of pixels PX of the active area AA. The link line area LNA is disposed between the island area ISA in which the third plate pattern 123P is disposed and the active area AA and is gradually widened (for example, radially formed) from the island area ISA to the active area AA. Further, the pattern layer 120 includes a plurality of fourth line patterns 124L which is disposed on the link line area LNA and is connected to the third plate pattern 123P disposed on the island area ISA and the plurality of link lines may be disposed on the third plate pattern 123P and the plurality of fourth line patterns 124L. That is, the plurality of link lines may be disposed to extend from the third plate pattern 123P to the plurality of fourth line patterns 124L. The plurality of link lines and fourth line patterns 124L will be described in more detail with reference to FIGS. 10 to 12.

Next, a plurality of fourth plate patterns 124P may be disposed in the third non-active areas NA3 on both sides of the second non-active area NA2. For example, the fourth plate patterns 124P are disposed in island shapes which are spaced apart from each other, like the first plate pattern 121P of the active area AA and the second plate pattern 122P of the first non-active area NA1 and the fifth line pattern 125L may connect adjacent fourth plate patterns 124P. A power link line which is connected to the power supply PS may be disposed on the fourth plate pattern 124P and the fifth line pattern 125L.

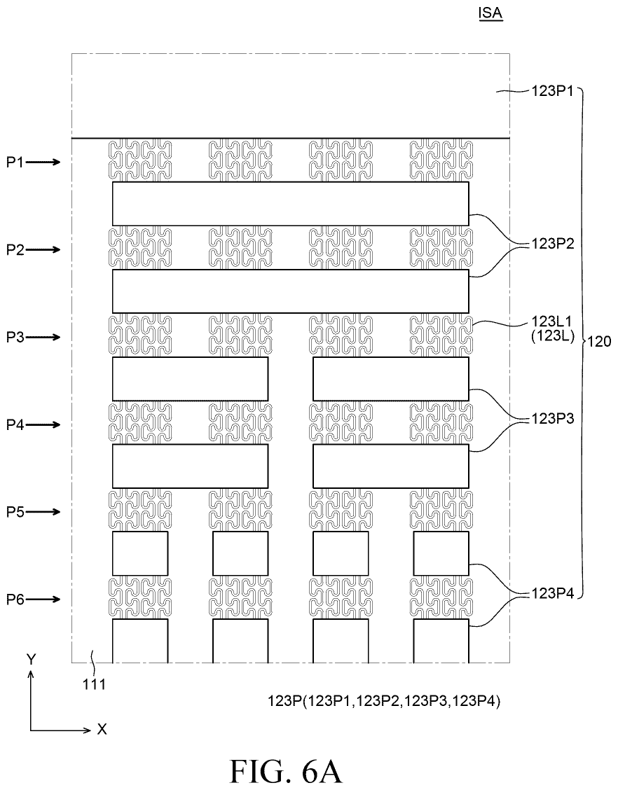

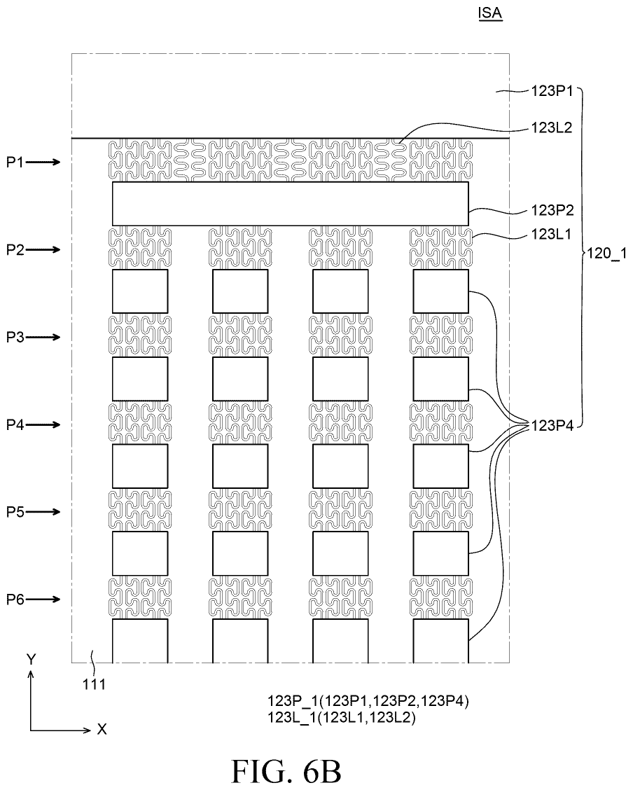

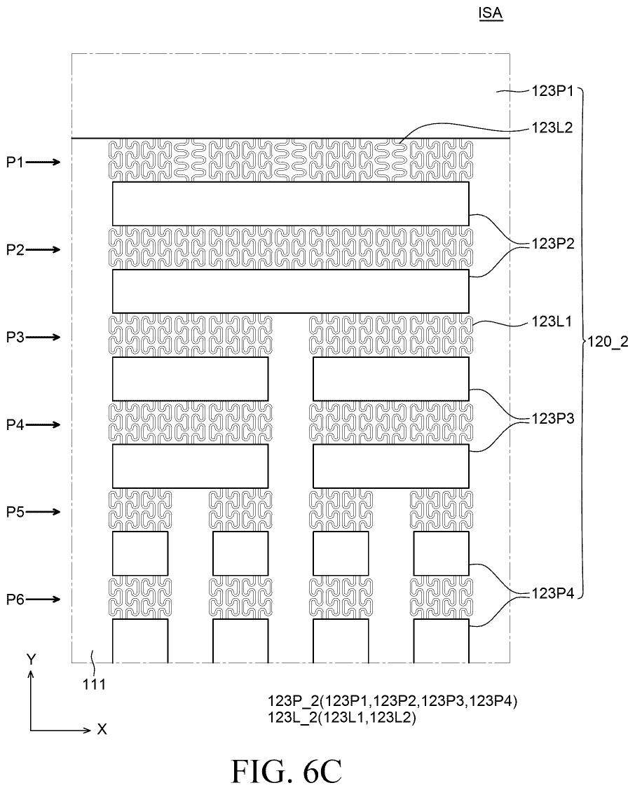

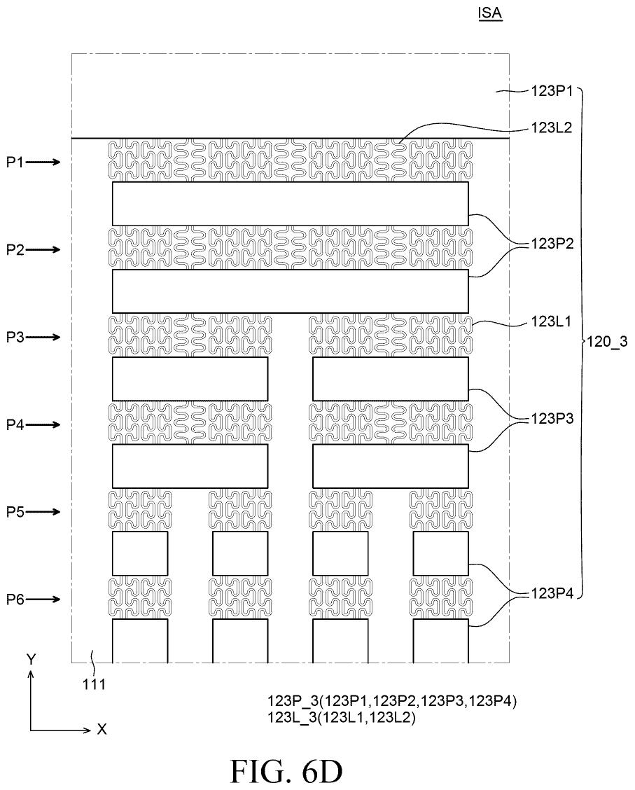

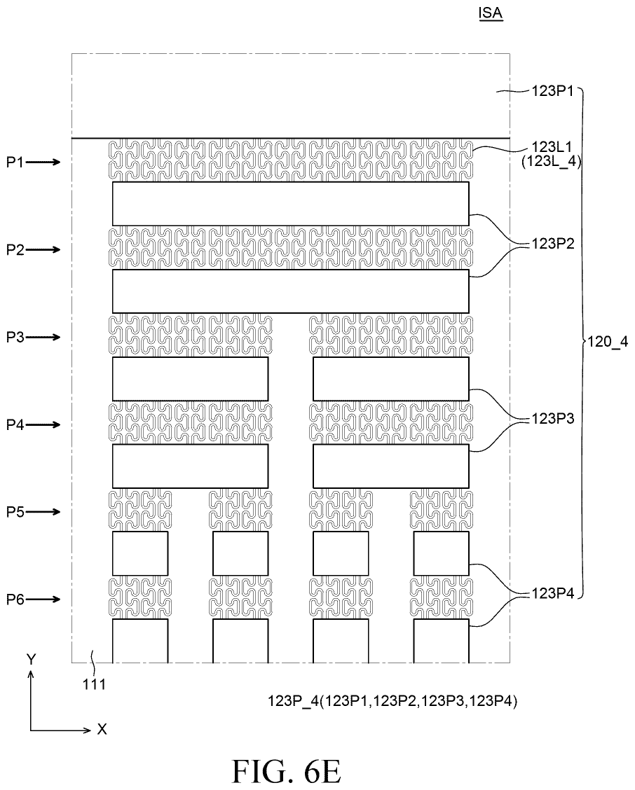

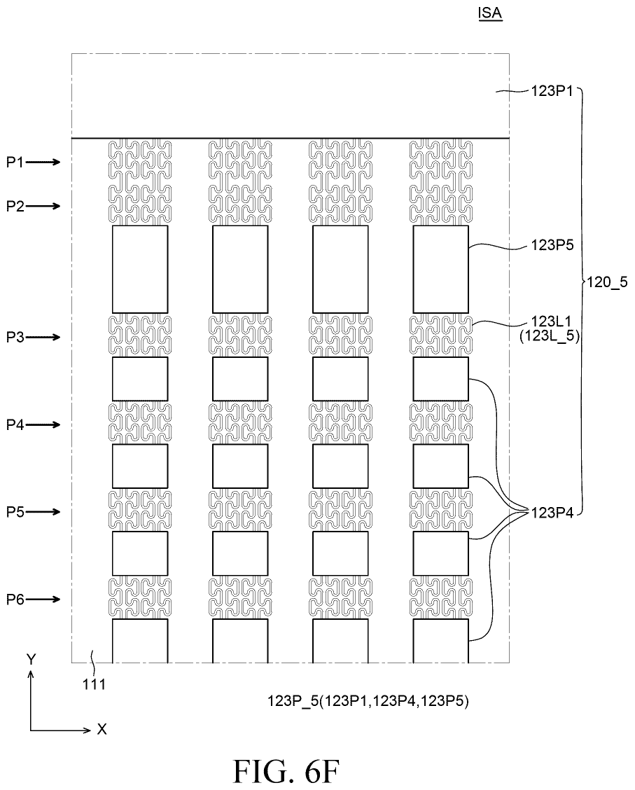

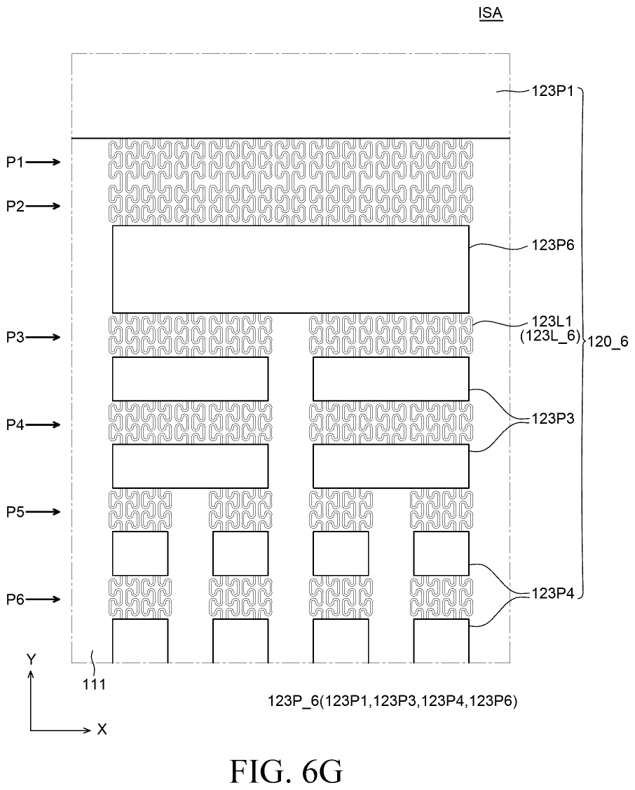

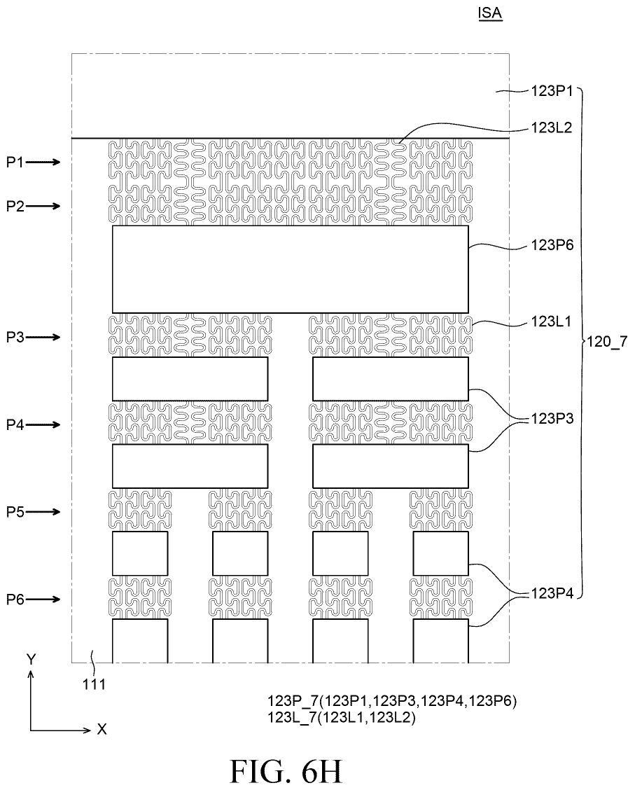

Hereinafter, the third plate pattern 123P and the third line pattern 123L disposed in the island area ISA of the display device 100 will be described in more detail with reference to FIGS. 6A to 9I and the link line disposed in the link line area LNA of the display device 100 will be described in more detail with reference to FIGS. 10 to 12.

FIGS. 6A to 6H are enlarged plan views illustrating an example of an island area of a display device of FIG. 5.

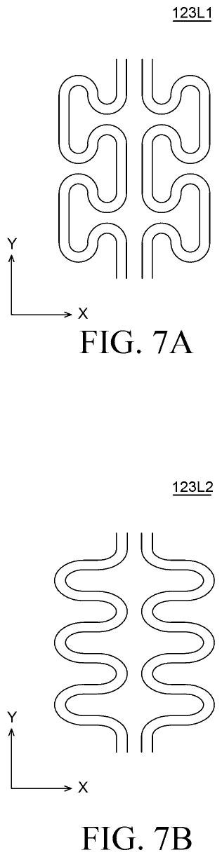

FIGS. 7A and 7B are views for explaining an example of a third line pattern included in a display device of FIG. 5.

For example, FIGS. 6A to 6H illustrate pattern layers 120, 120_1, 120_2, 120_3, 120_4, 120_5, 120_6, and 120_7 disposed on the island area ISA of the display device 100, for example, various exemplary embodiments of the third plate pattern 123P and the third line pattern 123L. Accordingly, the island area ISA of the display device 100 will be specifically described with reference to FIG. 6A and for the convenience of description, in FIGS. 6B to 6H, different parts from FIG. 6A will be mainly described and a redundant description will not be repeated.

First, referring to FIGS. 5 and 6A, the pattern layer 120 according to the exemplary embodiment of the present disclosure which is disposed on the island area ISA of the lower substrate 111 may include a plurality of third plate patterns 123P and a plurality of third line patterns 123L.

The plurality of third plate patterns 123P may include a 3-1-th plate pattern 123P1 having a first size, a 3-2-th plate pattern 123P2 having a second size, a 3-3-th plate pattern 123P3 having a third size, and a 3-4-th plate pattern 123P4 having a fourth size which are sequentially disposed to be spaced apart from each other along the second direction Y (or an opposite direction of the second direction Y).

In one exemplary embodiment, the 3-1-th plate pattern 123P1, the 3-2-th plate pattern 123P2, the 3-3-th plate pattern 123P3, and the 3-4-th plate pattern 123P4 included in the plurality of third plate patterns 123P may have different sizes (or areas). The size (or area) of the plurality of third plate patterns 123P may be gradually reduced toward the opposite direction of the second direction Y (or the size (or area) of the plurality of third plate patterns 123P is gradually increased toward the second direction Y). That is, the more adjacent to the active area AA, the smaller the size (or an area) of the plurality of third plate patterns 123P. In other words, a first size (or a first area) of the 3-1-th plate pattern 123P1 which is the most adjacent to the bonding area BDA in which the flexible film 130 is disposed, among the plurality of third plate patterns 123P, is the largest. Further, a fourth size (or a fourth area) of the 3-4-th plate pattern 123P4 which is the most adjacent to the link line area LNA, among the plurality of third plate patterns 123P may be the smallest. In other words, the first size is larger than the second size, the second size is larger than the third size, and the third size may be larger than the fourth size.

According to the exemplary embodiment, as illustrated in FIG. 6A, the 3-1-th plate pattern 123P1, the 3-2-th plate pattern 123P2, the 3-3-th plate pattern 123P3, and the 3-4-th plate pattern 123P4 have the same width in the vertical direction (for example, the second direction Y), but have different widths in the horizontal direction (for example, the first direction X). For example, in the case of the plurality of third plate patterns 123P, the width of the plurality of third plate patterns 123P in the horizontal direction (for example, the first direction X) is gradually reduced toward the opposite direction of the second direction Y (or the width of the plurality of third plate patterns 123P in the horizontal direction (for example, the first direction X) is gradually increased toward the second direction Y.

Further, the size of the plurality of third plate patterns 123P is gradually reduced toward the opposite direction of the second direction Y. Therefore, the number of each of the 3-1-th plate pattern 123P1, the 3-2-th plate pattern 123P2, the 3-3-th plate pattern 123P3, and the 3-4-th plate pattern 123P4 in the unit area is gradually increased toward the opposite direction of the second direction Y. For example, in FIG. 6A, it is illustrated that the plurality of third plate patterns 123P includes one 3-1-th plate pattern 123P1, two 3-2-th plate patterns 123P2, four 3-3-th plate patterns 123P3, and eight 3-4-th plate patterns 123P4, but the exemplary embodiment of the present disclosure is not limited thereto.

In the meantime, even though in FIG. 6A, it is illustrated that the 3-1-th plate pattern 123P1, the 3-2-th plate pattern 123P2, the 3-3-th plate pattern 123P3, and the 3-4-th plate pattern 123P4 are formed in a quadrangular shape, for example, a rectangle or a square, but are not limited thereto.

The plurality of third line patterns 123L may include a 3-1-th line pattern 123L1 having a first shape. The 3-1-th line pattern 123L1 may connect third plate patterns 123P3 which are adjacent to each other along the second direction Y. For example, the 3-1-th line pattern 123L1 connects the 3-1-th plate pattern 123P1 and the 3-2-th plate pattern 123P2 which are adjacent, in a first position P1 between the 3-1-th plate pattern 123P1 and the 3-2-th plate pattern 123P2 which are adjacent in the second direction Y. The 3-1-th line pattern 123L1 connects the adjacent 3-2-th plate patterns 123P2 in a second position P2 between the plurality of 3-2-th plate patterns 123P2 which is adjacent in the second direction Y. The 3-1-th line pattern 123L1 connects the 3-2-th plate pattern 123P2 and the 3-3-th plate pattern 123P3 which are adjacent, in a third position P3 between the 3-2-th plate pattern 123P2 and the 3-3-th plate pattern 123P3 which are adjacent in the second direction Y. The 3-1-th line pattern 123L1 connects the adjacent 3-3-th plate patterns 123P3, in a fourth position P4 between the plurality of 3-3-th plate patterns 123P3 which is adjacent in the second direction Y. The 3-1-th line pattern 123L1 connects the 3-3-th plate pattern 123P3 and the 3-4-th plate pattern 123P4 which are adjacent, in a fifth position P5 between the 3-3-th plate pattern 123P3 and the 3-4-th plate pattern 123P4 which are adjacent in the second direction Y. The 3-1-th line pattern 123L1 may connect the adjacent 3-4-th plate patterns 123P4 in a sixth position P6 between the plurality of 3-4-th plate patterns 123P4 which is adjacent in the second direction Y.

The plurality of 3-1-th line patterns 123L1 may have a wavy shape. For example, the plurality of 3-1-th line patterns 123L1 has a first wavy shape having a first length ratio. Here, the length ratio is defined by a ratio of a length of a line having a curved shape in a non-stretched state (for example, a distance between both ends of the corresponding wiring line in a non-stretched state in which a force is not applied to the corresponding wiring line to have a curved shape) and a length of the corresponding wiring line in a maximum extended state (for example, a distance between both ends of the corresponding wiring line which is deformed to have a straight according to the maximum stretched when the force is applied to the corresponding wiring line to be extended). For example, the smaller the length ratio, the fewer times the corresponding wiring line is bent.

In the meantime, as described with reference to FIG. 5, the plurality of link lines is formed on the plurality of third plate patterns 123P and the plurality of third line patterns 123L to extend to the link line area LNA. For example, the plurality of link lines is formed as a straight line in the plurality of third plate patterns 123P, for example, in the 3-1-th plate pattern 123P1, the 3-2-th plate pattern 123P2, the 3-3-th plate pattern 123P3, and the 3-4-th plate pattern 123P4. Further, the plurality of link lines may be formed in a wavy shape along the shape of the 3-1-th line pattern 123L1, in the plurality of third line patterns 123L, for example, in the 3-1-th line pattern 123L1.

Further, in the island area ISA, the plurality of third plate patterns 123P and the plurality of third line patterns 123L which connects adjacent third plate patterns 123P and has a stretchability are disposed to be freely stretched or bended. Therefore, the second non-active area NA2, for example, the island area ISA has a stretchability together with the active area AA to be flexibly deformed.

Further, as described above, in the case of the display device 100 according to the exemplary embodiment of the present disclosure, a size (or an area) of the third plate pattern 123P disposed in the island area ISA is gradually reduced toward an opposite direction of the second direction Y, that is, a direction from the flexible film 130 to the active area AA. Therefore, when the display device 100 is stretched, the stretching stress for the third line pattern 123L and the plurality of link lines disposed on the third line pattern 123L may be more effectively dispersed so that the damage or crack of the pattern layer 120 included in the display device 100 may be suppressed.

In one exemplary embodiment, the plurality of third plate patterns 123P and the plurality of third line patterns 123L may be rigid patterns. For example, the plurality of third plate patterns 123P and the plurality of third line patterns 123L may be more rigid than the lower substrate 111 and the upper substrate 112.

The plurality of third plate patterns 123P and the plurality of third line patterns 123L which are rigid substrates may be formed of a plastic material having flexibility lower than that of the lower substrate 111 and the upper substrate 112. For example, the plurality of third plate patterns 123P and the plurality of third line patterns 123L may include at least one of polyimide (PI), polyacrylate, and polyacetate. According to the exemplary embodiment, the plurality of third plate patterns 123P and the plurality of third line patterns 123L may include the same material. At this time, when the plurality of third plate patterns 123P and the plurality of third line patterns 123L include the same material, the plurality of third plate patterns 123P and the plurality of third line patterns 123L may be integrally formed.

Moduli of elasticity of the plurality of third plate patterns 123P and the plurality of third line patterns 123L may be higher than moduli of elasticity of the lower substrate 111 and the upper substrate 112. For example, moduli of elasticity of the plurality of third plate patterns 123P and the plurality of third line patterns 123L may be 1000 times higher than the modulus of elasticity of the lower substrate 111 and the upper substrate 112, but the exemplary embodiment of the present disclosure is not limited thereto.

Next, referring to FIG. 6B, the pattern layer 120_1 according to another exemplary embodiment of the present disclosure which is disposed on the island area ISA of the lower substrate 111 may include the plurality of third plate patterns 123P_1 and the plurality of third line patterns 123L_1.

The plurality of third plate patterns 123P_1 may include a 3-1-th plate pattern 123P1 having a first size, a 3-2-th plate pattern 123P2 having a second size, and a 3-4-th plate pattern 123P4 having a fourth size which are sequentially disposed to be spaced apart from each other along the second direction Y (or an opposite direction of the second direction Y).

In one exemplary embodiment, the 3-1-th plate pattern 123P1, the 3-2-th plate pattern 123P2, and the 3-4-th plate pattern 123P4 included in the plurality of third plate patterns 123P_1 may have different sizes (or areas). For example, the size (or area) of the plurality of third plate patterns 123P_1 may be gradually reduced toward the opposite direction of the second direction Y (or the size (or area) of the plurality of third plate patterns 123P_1 is gradually increased toward the second direction Y). For example, as described with reference to FIG. 6A, a first size (or a first area) of the 3-1-th plate pattern 123P1 which is the most adjacent to the bonding area BDA in which the flexible film 130 is disposed, among the plurality of third plate patterns 123P_1, is the largest.

Further, a fourth size (or a fourth area) of the 3-4-th plate pattern 123P4 which is the most adjacent to the link line area LNA in which the plurality of link lines is disposed, among the plurality of third plate patterns 123P_1, may be the smallest.

Further, the size of the plurality of third plate patterns 123P_1 is gradually reduced toward the opposite direction of the second direction Y. Therefore, the number of each of the 3-1-th plate pattern 123P1, the 3-2-th plate pattern 123P2, and the 3-4-th plate pattern 123P4 in the unit area may be gradually increased toward the opposite direction of the second direction Y. For example, in FIG. 6B, it is illustrated that the plurality of third plate patterns 123P_1 includes one 3-1-th plate pattern 123P1, one 3-2-th plate patterns 123P2, and twenty 3-4-th plate patterns 123P4, but the exemplary embodiment of the present disclosure is not limited thereto. For example, the plurality of third plate patterns includes one 3-1-th plate pattern, one 3-2-th plate pattern, and twenty 3-4-th plate pattern which are sequentially disposed along an opposite direction of the second direction. A first size of the 3-1-th plate pattern is larger than a second size of the 3-2-th plate pattern, and the second size of the 3-2-th plate pattern is larger than a fourth size of the 3-4-th plate pattern. Widths of the 3-1-th plate pattern, the 3-2-th plate pattern, and the 3-4-th plate pattern in the first direction are reduced toward an opposite direction of the second direction. Widths of the 3-1-th plate pattern, the 3-2-th plate pattern, and the 3-4-th plate pattern are the same in the second direction. However, the present disclosure is not limited thereto.

In one exemplary embodiment, the plurality of third line patterns 123L_1 may include a 3-1-th line pattern 123L1 having a first shape and a 3-2-th line pattern 123L2 having a second shape.

The 3-1-th line pattern 123L1 may connect third plate patterns 123P_1 which are adjacent to each other along the second direction Y. For example, the 3-1-th line pattern 123L1 connects the 3-1-th plate pattern 123P1 and the 3-2-th plate pattern 123P2 which are adjacent, in a first position P1 between the 3-1-th plate pattern 123P1 and the 3-2-th plate pattern 123P2 which are adjacent in the second direction Y. The 3-1-th line pattern 123L1 connects the 3-2-th plate pattern 123P2 and the 3-4-th plate pattern 123P4 which are adjacent, in a second position P2 between the 3-2-th plate pattern 123P2 and the 3-4-th plate pattern 123P4 which are adjacent in the second direction Y. The 3-1-th line pattern 123L1 may connect the adjacent 3-4-th plate patterns 123P4 in each of third to sixth positions P3, P4, P5, and P6 between the plurality of 3-4-th plate patterns 123P4 which is adjacent in the second direction Y.

Further, the 3-2-th line pattern 123L2 may connect third plate patterns 123P_2 which are adjacent along the second direction Y. For example, the 3-2-th line pattern 123L2 is disposed between the 3-1-th plate pattern 123P1 and the 3-2-th plate pattern 123P2 which are adjacent in the second direction Y, in the first position P1 adjacent to the bonding area BDA in which the flexible film 130 is disposed to connect the 3-1-th plate pattern 123P1 and the 3-2-th plate pattern 123P2 which are adjacent in the second direction Y. For example, the 3-2-th line pattern 123L2 is disposed between the 3-1-th line patterns 123L1 which are adjacent in the first direction X in the first position P1 to connect the 3-1-th plate pattern 123P1 and the 3-2-th plate pattern 123P2 adjacent in the second direction Y.

The plurality of 3-1-th line patterns 123L1 and the plurality of 3-2-th line patterns 123L2 may have a wavy shape. The shape of the 3-1-th line patterns 123L1 and the 3-2-th line patterns 123L2 will be more specifically disposed with reference to FIGS. 7A and 7B. The plurality of 3-1-th line patterns 123L1 has a first wavy shape having a first length ratio and the plurality of 3-2-th line patterns 123L2 may have a second wavy shape having a second length ratio.

In one exemplary embodiment, the first length ratio of the 3-1-th line pattern 123L1 may be larger than the second length ratio of the 3-2-th line pattern 123L2. Accordingly, when a force along the second direction Y is applied to the display device 100, the stretchability of the 3-2-th line pattern 123L2 may be lower than the stretchability of the 3-1-th line pattern 123L1. Accordingly, in the exemplary embodiment of FIG. 6B, the excessive stretching of the island area ISA of the display device 100 may be suppressed by the 3-2-th line pattern 123L2 having a length ratio smaller than the first length ratio. Therefore, the damage or crack of the pattern layer 120_1 included in the display device 100 may be more effectively suppressed.

In the meantime, as described with reference to FIG. 5, the plurality of link lines is formed on the plurality of third plate patterns 123P_1 and the plurality of third line patterns 123L_1 to extend to the link line area LNA. For example, the plurality of link lines is formed as a straight line in the plurality of third plate patterns 123P_1, for example, in the 3-1-th plate pattern 123P1, the 3-2-th plate pattern 123P2, and the 3-4-th plate pattern 123P4. Further, the plurality of link lines may be formed in a wavy shape along the shape of the 3-1-th line pattern 123L1, in the plurality of 3-1-th line pattern 123L1 among the plurality of third line patterns 123L. According to the exemplary embodiment, the plurality of link lines is not disposed above the 3-2-th line pattern 123L2 for suppressing the excessive stretching.

Further, as described above, the size (or the area) of the third plate pattern 123P_1 disposed in the island area ISA is gradually reduced toward the opposite direction of the second direction Y, that is, a direction from the flexible film 130 to the active area AA. Therefore, the stretching stress for the third line pattern 123L_1 and the plurality of link lines disposed on the third line pattern 123L_1 when the display device 100 is stretched may be more effectively dispersed.

Next, referring to FIG. 6C, a pattern layer 120_2 according to still another exemplary embodiment of the present disclosure which is disposed on the island area ISA of the lower substrate 111 may include a plurality of third plate patterns 123P_2 and a plurality of third line patterns 123L_2.

The plurality of third plate patterns 123P_2 may include a 3-1-th plate pattern 123P1 having a first size, a 3-2-th plate pattern 123P2 having a second size, a 3-3-th plate pattern 123P3 having a third size, and a 3-4-th plate pattern 123P4 having a fourth size which are sequentially disposed to be spaced apart from each other along the second direction Y (or an opposite direction of the second direction Y). In the meantime, in the exemplary embodiment of FIG. 6C, the 3-1-th plate pattern 123P1, the 3-2-th plate pattern 123P2, the 3-3-th plate pattern 123P3, and the 3-4-th plate pattern 123P4 included in the plurality of third plate patterns 123P_2 are substantially the same as or similar to the 3-1-th plate pattern 123P1, the 3-2-th plate pattern 123P2, the 3-3-th plate pattern 123P3, and the 3-4-th plate pattern 123P4 included in the plurality of third plate patterns 123P which have been described with reference to FIG. 6A. Therefore, the redundant description will not be repeated.

In one exemplary embodiment, the plurality of third line patterns 123L_2 may include a 3-1-th line pattern 123L1 having a first shape and a 3-2-th line pattern 123L2 having a second shape. In the meantime, in the exemplary embodiment of FIG. 6C, the 3-1-th line pattern 123L1 and the 3-2-th line pattern 123L2 included in the plurality of third line patterns 123L_2 are substantially the same as or similar to the 3-1-th line pattern 123L1 and the 3-2-th line pattern 123L2 included in the plurality of third line patterns 123L_1 which have been described with reference to FIG. 6B. Therefore, the redundant description will not be repeated.

As described above, the size (or the area) of the third plate pattern 123P_2 included in the pattern layer 120_2 disposed on the island area ISA is gradually reduced toward the opposite direction of the second direction Y, that is, a direction from the flexible film 130 to the active area AA. Therefore, the stretching stress for the third line pattern 123L_2 and the plurality of link lines disposed on the third line pattern 123L_2 when the display device 100 is stretched is more effectively dispersed. The plurality of third line patterns 123L2_2 includes a 3-2-th line pattern 123L2 having a relatively low stretchability to suppress the excessive stretching of the island area ISA of the display device 100. Accordingly, the damage or crack of the pattern layer 120_2 included in the display device 100 may be more effectively suppressed.

In the meantime, in FIGS. 6B and 6C, it has been described that the 3-2-th line pattern 123L2 is disposed only in the first position P1 between the 3-1-th line patterns 123L1 which are adjacent in the first direction X to connect the 3-1-th plate pattern 123P1 and the 3-2-th plate pattern 123P2 adjacent in the second direction Y. However, the exemplary embodiment of the present disclosure is not limited thereto.

For example, referring to FIG. 6D, a pattern layer 120_3 according to still another exemplary embodiment of the present disclosure which is disposed on the island area ISA of the lower substrate 111 may include a plurality of third plate patterns 123P_3 and a plurality of third line patterns 123L_3. Here, the plurality of third plate patterns 123P_3 is substantially the same as the plurality of third plate patterns 123P which has been described with reference to FIG. 6A so that a redundant description will not be repeated.

The plurality of third line patterns 123L_3 may include a 3-1-th line pattern 123L1 having a first shape and a 3-2-th line pattern 123L2 having a second shape.

The 3-2-th line pattern 123L2 may connect third plate patterns 123P_3 which are adjacent to each other along the second direction Y. For example, the 3-2-th line pattern 123L2 is disposed between the 3-1-th plate pattern 123P1 and the 3-2-th plate pattern 123P2 which are adjacent in the second direction Y, in the first position P1 adjacent to the bonding area BDA in which the flexible film 130 is disposed to connect the 3-1-th plate pattern 123P1 and the 3-2-th plate pattern 123P2 which are adjacent in the second direction Y. The 3-2-th line pattern 123L2 connects the adjacent 3-2-th plate patterns 123P2, in a second position P2 between the plurality of 3-2-th plate patterns 123P2 which is adjacent in the second direction Y. The 3-2-th line pattern 123L2 connects the 3-2-th plate pattern 123P2 and the 3-3-th plate pattern 123P3 which are adjacent, in a third position P3 between the 3-2-th plate pattern 123P2 and the 3-3-th plate pattern 123P3 which are adjacent in the second direction Y. The 3-2-th line pattern 123L2 may connect the adjacent 3-3-th plate patterns 123P3, in a fourth position P4 between the plurality of 3-3-th plate patterns 123P3 which is adjacent in the second irection Y.

As described bove, in the exemplary embodiment of FIG. 6D, as compared with the exemplary embodiment of FIGS. 6B and 6C, the 3-2-th line pattern 123L2 for suppressing the excessive stretching is disposed not only in the first position P1, but also in the second to fourth positions P2, P3, and P4. Accordingly, the excessive stretching of the island area ISA of the display device 100 may be effectively suppressed by the 3-2-th line pattern 123L2.

In the meantime, even though in FIG. 6D, it has been described that the 3-2-th line pattern 123L2 having a second length ratio is disposed between the 3-1-th line patterns 123L1 which have a first length ratio and adjacent in the first direction X, in each of the first to fourth positions P1, P2, P3, and P4. However, the exemplary embodiment of the present disclosure is not limited thereto.

For example, referring to FIG. 6E, a pattern layer 120_4 according to still another exemplary embodiment of the present disclosure which is disposed on the island area ISA of the lower substrate 111 includes a plurality of third plate patterns 123P_4 and a plurality of third line patterns 123L_4. In the exemplary embodiment of FIG. 6E, as compared with the exemplary embodiment of FIG. 6D, the plurality of third line patterns 123L_4 may include only a 3-1-th line pattern 123L1 having a first length ratio. As described above, the plurality of third line patterns 123L_4 includes only the 3-1-th line pattern 123L1 having the same shape so that the manufacturing process of the display device 100 may be more simplified.

Next, referring to FIG. 6F, a pattern layer 120_5 according to still another exemplary embodiment of the present disclosure which is disposed on the island area ISA of the lower substrate 111 may include a plurality of third plate patterns 123P_5 and a plurality of third line patterns 123L_5.

The plurality of third plate patterns 123P_5 is sequentially disposed to be spaced apart from each other along the second direction Y (or an opposite direction of the second direction Y). The plurality of third plate patterns 123P_5 may include a 3-1-th plate pattern 123P1 having a first size, a 3-5-th plate pattern 123P5 having a fifth size, and a 3-4-th plate pattern 123P4 having a fourth size.

In one exemplary embodiment, the 3-1-th plate pattern 123P1, the 3-5-th plate pattern 123P5, and the 3-4-th plate pattern 123P4 included in the plurality of third plate patterns 123P_5 may have different sizes (or areas). For example, the size (or area) of the plurality of third plate patterns 123P_5 may be gradually reduced toward the opposite direction of the second direction Y (or the size (or area) of the plurality of third plate patterns 123P_5 is gradually increased toward the second direction Y). For example, a first size (or a first area) of the 3-1-th plate pattern 123P1 which is the most adjacent to the bonding area BDA in which the flexible film 130 is disposed, among the plurality of third plate patterns 123P_5 is the largest. A fifth size (or a fifth area) of the 3-5-th plate pattern 123P5 which is adjacent to the 3-1-th plate pattern 123P1 in the second direction Y is smaller than the first size (or first area). A fourth size (or a fourth area) of the 3-4-th plate pattern 123P4 which is adjacent to the 3-5-th plate pattern 123P5 in the second direction Y may be smaller than the fifth size (or fifth area).

Specifically, the 3-1-th plate pattern 123P1, the 3-5-th plate pattern 123P5, and the 3-4-th plate pattern 123P4 included in the third plate pattern 123P3_5 have the same width in the horizontal direction (for example, the first direction X) and have different widths in the vertical direction (for example, the second direction Y). For example, in the case of the plurality of third plate patterns 123P_5, the width of the plurality of third plate patterns 123P_5 in the vertical direction (for example, the second direction Y) is gradually reduced toward the opposite direction of the second direction Y (or the width of the plurality of third plate patterns 123P_5 in the vertical direction (for example, the second direction Y) is gradually increased toward the second direction Y).

In one exemplary embodiment, the plurality of third line patterns 123L_5 may include a 3-1-th line pattern 123L1 having a first shape and a 3-2-th line pattern 123L2 having a second shape.

The plurality of third line patterns 123L_5 may include a 3-1-th line pattern 123L1 having a first shape. The 3-1-th line pattern 123L1 may connect third plate patterns 123P_5 which are adjacent to each other along the second direction Y. For example, the 3-1-th line pattern 123L1 connects the 3-1-th plate pattern 123P1 and the 3-5-th plate pattern 123P5 which are adjacent, in the first position P1 and the second position P2 between the 3-1-th plate pattern 123P1 and the 3-5-th plate pattern 123P5 which are adjacent in the second direction Y. The 3-1-th line pattern 123L1 connects the 3-5-th plate pattern 123P5 and the 3-4-th plate pattern 123P4 which are adjacent, in a third position P3 between the 3-5-th plate pattern 123P5 and the 3-4-th plate pattern 123P4 which are adjacent in the second direction Y. The 3-1-th line pattern 123L1 may connect the adjacent 3-4-th plate patterns 123P4 in fourth to sixth positions P4, P5, and P6 between the plurality of 3-4-th plate patterns 123P4 which is adjacent in the second direction Y. According to the exemplary embodiment, referring to FIG. 6F, two 3-1-th line patterns 123L1 which are adjacent along the second direction Y are connected in every column in the first position P1 and the second position P2 between the 3-1-th plate pattern 123P1 and the 3-5-th plate pattern 123P5 adjacent in the second direction Y to connect the 3-1-th plate pattern 123P1 and the 3-5-th plate pattern 123P5 which are adjacent in the second direction Y. For example, the plurality of third plate patterns includes one 3-1-th plate pattern, four 3-5-th plate pattern, and sixteen 3-4-th plate pattern which are sequentially disposed along an opposite direction of the second direction. Each of a width of the 3-5-th plate pattern in the first direction and a width of the 3-4-th plate pattern in the first direction is less than a width of the 3-1-th plate pattern in the first direction, and a width of the 3-5-th plate pattern and a width of the 3-4-th plate pattern in the first direction are same. A width of the 3-5-th plate pattern in the second direction is greater than a width of the 3-4-th plate pattern in the second direction. However, the present disclosure is not limited thereto.

Next, referring to FIG. 6G, FIG. 6G illustrates a modified embodiment of FIG. 6F with regard to the shape of a third plate pattern 123P_6.

Specifically, referring to FIG. 6G, a pattern layer 120_6 according to still another exemplary embodiment of the present disclosure which is disposed on the island area ISA of the lower substrate 111 may include a plurality of third plate patterns 123P_6 and a plurality of third line patterns 123L_6.

The plurality of third plate patterns 123P_6 includes a 3-1-th plate pattern 123P1 having a first size, a 3-6-th plate pattern 123P6 having a sixth size, a 3-3-th plate pattern 123P3 having a third size, and a 3-4-th plate pattern 123P4 having a fourth size which are sequentially disposed to be spaced apart from each other along the second direction Y (or an opposite direction of the second direction Y).

In one exemplary embodiment, the 3-1-th plate pattern 123P1, the 3-6-th plate pattern 123P6, the 3-3-th plate pattern 123P3, and the 3-4-th plate pattern 123P4 included in the plurality of third plate patterns 123P_6 may have different sizes (or areas). For example, the size (or area) of the plurality of third plate patterns 123P_6 may be gradually reduced toward the opposite direction of the second direction Y (or the size (or area) of the plurality of third plate patterns 123P_6 is gradually increased toward the second direction Y). For example, a first size (or a first area) of the 3-1-th plate pattern 123P1 which is the most adjacent to the bonding area BDA in which the flexible film 130 is disposed, among the plurality of third plate patterns 123P_6 is the largest. A sixth size (or a sixth area) of the 3-6-th plate pattern 123P6 which is adjacent to the 3-1-th plate pattern 123P1 in the second direction Y is smaller than the first size (or first area). A third size (or a third area) of the 3-3-th plate pattern 123P3 which is adjacent to the 3-6-th plate pattern 123P6 in the second direction Y is smaller than the sixth size (or sixth area). A fourth size (or a fourth area) of the 3-4-th plate pattern 123P4 which is adjacent to the 3-3-th plate pattern 123P3 in the second direction Y may be smaller than the third size (or third area).

Specifically, the 3-1-th plate pattern 123P1, the 3-6-th plate pattern 123P6, the 3-3-th plate pattern 123P3, and the 3-4-th plate pattern 123P4 included in the plurality of third plate pattern 123P_6 may have different widths in the horizontal direction (for example, the first direction X) and widths in the vertical direction (for example, the second direction Y). For example, in the case of the plurality of third plate patterns 123P_6, the width of the horizontal direction (for example, the first direction X) and the width of the vertical direction (for example, the second direction Y) of the plurality of third plate patterns 123P_6 may be gradually reduced toward the opposite direction of the second direction Y.

In the meantime, even though in FIG. 6G, it is illustrated that the third line pattern 123L_6 includes only a 3-1-th line pattern 123L1 having a first shape with a first length ratio, but the exemplary embodiment of the present disclosure is not limited thereto.

For example, further referring to FIG. 6H, FIG. 6H illustrates a modified embodiment for FIG. 6G with regard to a third line pattern 123L_7.

Specifically, referring to FIG. 6H, a pattern layer 120_7 according to still another exemplary embodiment of the present disclosure which is disposed on the island area ISA of the lower substrate 111 includes a plurality of third plate patterns 123P_7 and a plurality of third line patterns 123L_7. In the meantime, the plurality of third plate patterns 123P_7 included in the pattern layer 120_7 is substantially the same as or similar to the plurality of third plate patterns 123P_6 included in the pattern layer 120_6 which has been described with reference to FIG. 6G, so that a redundant description will not be repeated.

The plurality of third line patterns 123L_7 may include a 3-1-th line pattern 123L1 having a first shape and a 3-2-th line pattern 123L2 having a second shape.

The 3-2-th line pattern 123L2 may connect third plate patterns 123P_3 which are adjacent to each other along the second direction Y. For example, the 3-2-th line pattern 123L2 is disposed between the 3-1-th plate pattern 123P1 and the 3-6-th plate pattern 123P6 which are adjacent in the second direction Y, in the first position P1 and the second position P2 adjacent to the bonding area BDA in which the flexible film 130 is disposed to connect the 3-1-th plate pattern 123P1 and the 3-6-th plate pattern 123P6 which are adjacent in the second direction Y. The 3-2-th line pattern 123L2 connects the 3-6-th plate pattern 123P6 and the 3-3-th plate pattern 123P3 adjacent in a third position P3 between the 3-6-th plate pattern 123P6 and the 3-3-th plate pattern 123P3 which are adjacent in the second direction Y. The 3-2-th line pattern 123L2 may connect the adjacent 3-3-th plate patterns 123P3 in a fourth position P4 between the plurality of 3-3-th plate patterns 123P3 which is adjacent in the second direction Y.

As described above, the third line pattern 123L_7 included in the pattern layer 120_7 includes the 3-2-th line pattern 123L2 having a second length ratio for suppressing the excessive stretching. Accordingly, the excessive stretching of the island area ISA of the display device 100 may be suppressed to effectively suppress the damage or the crack of the pattern layer 120_7 included in the display device 100.

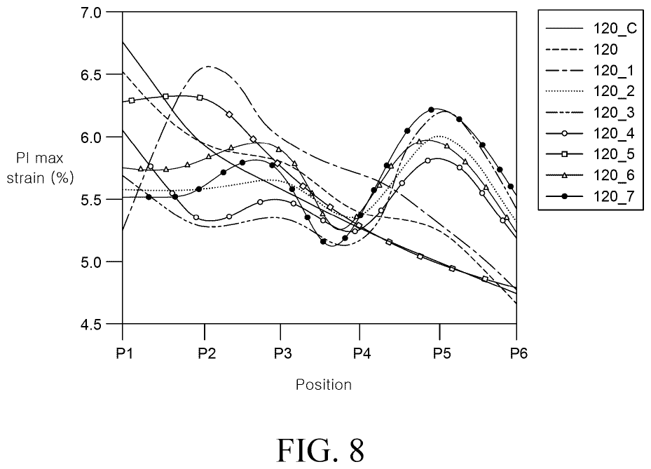

FIG. 8 is a graph for explaining examples of a stretching stress applied to a line pattern when a display device according to exemplary embodiments of the present disclosure is stretched.

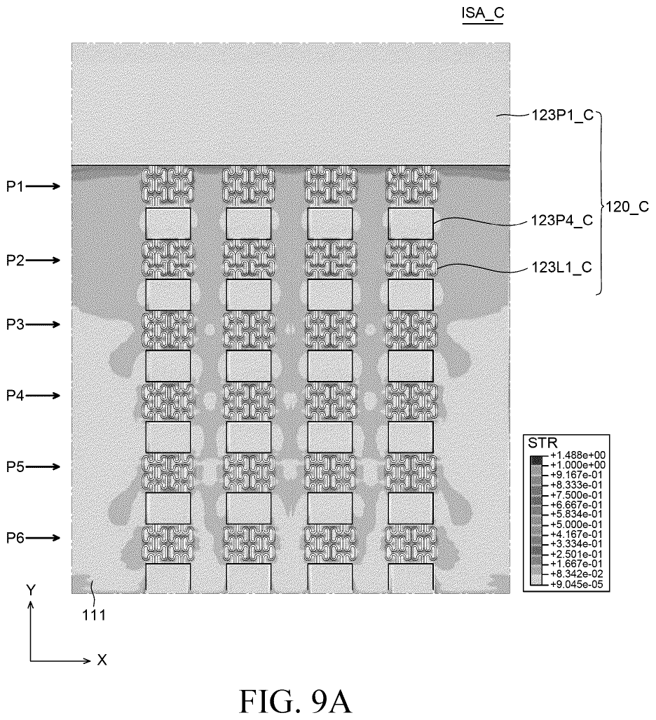

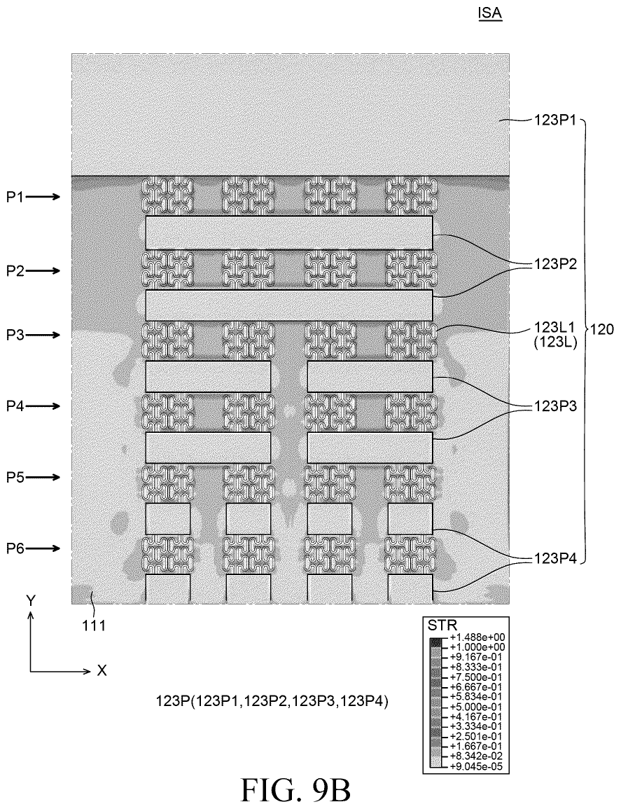

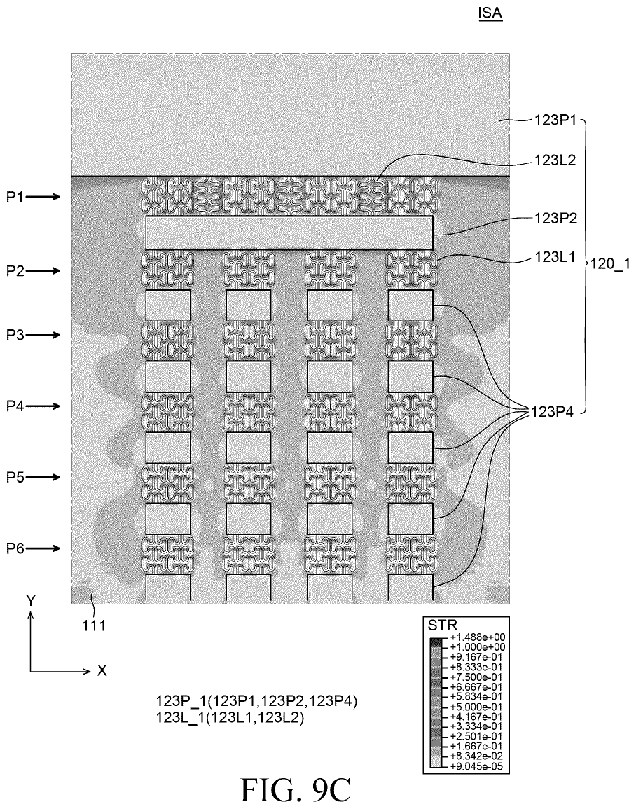

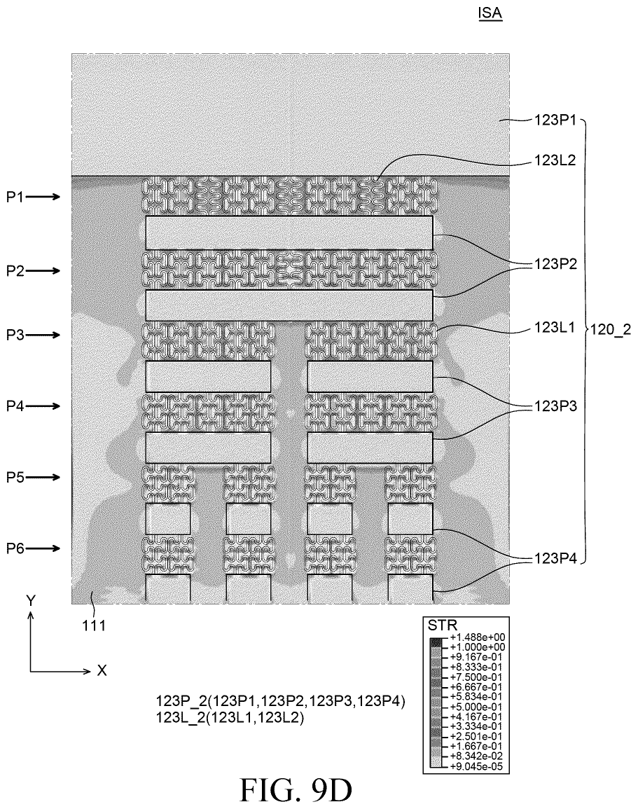

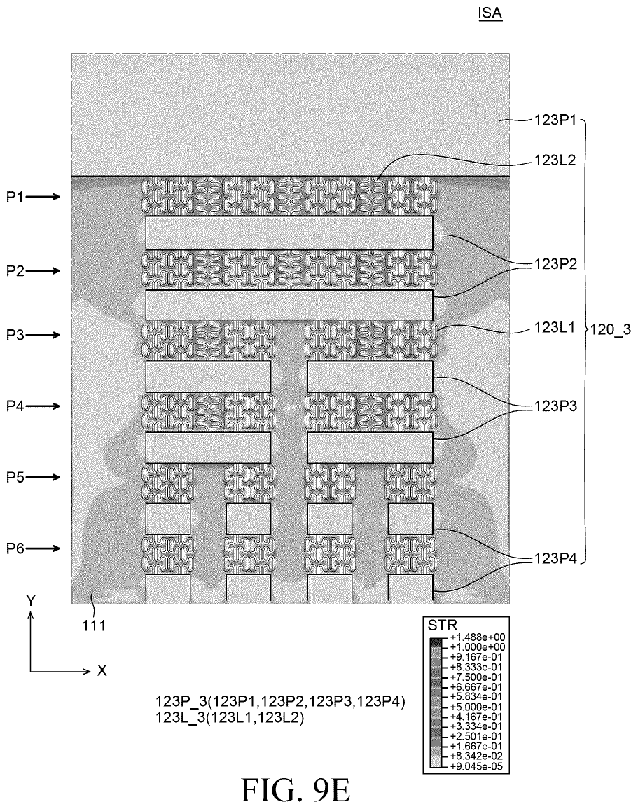

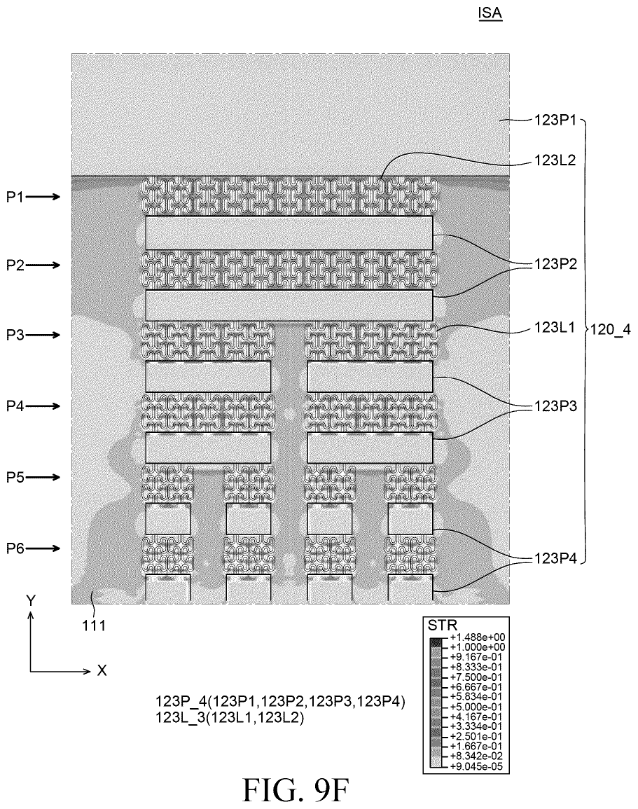

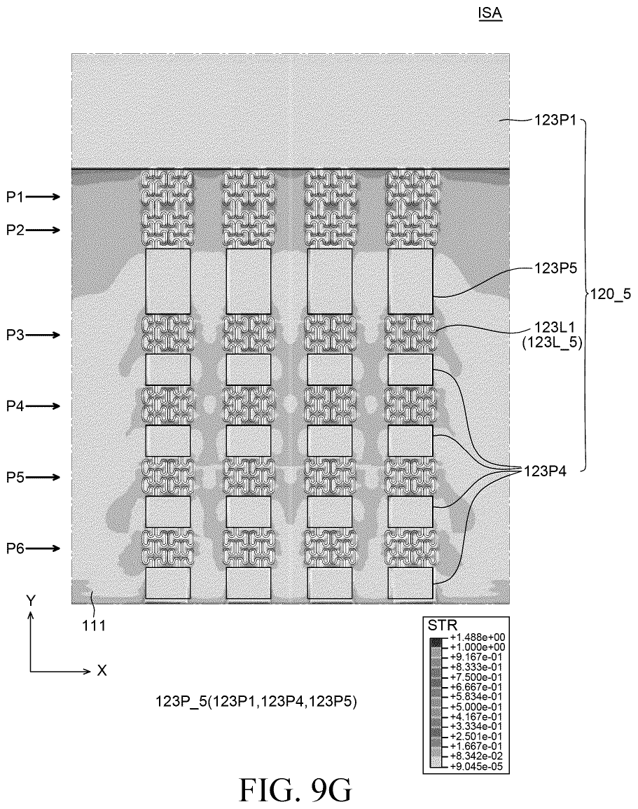

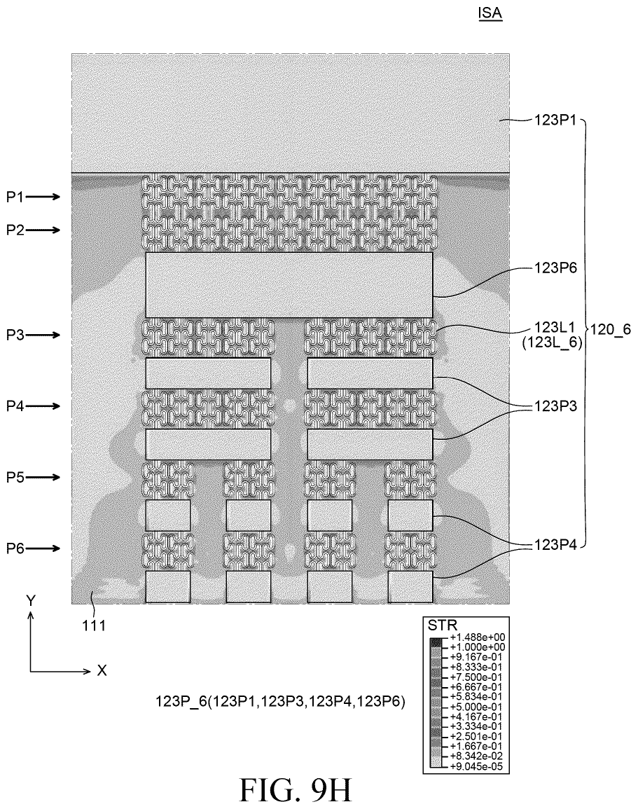

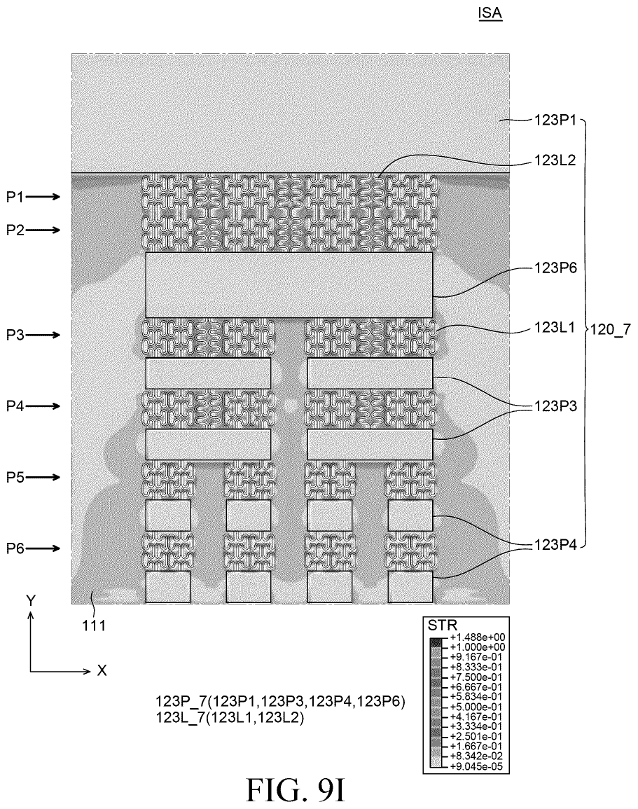

FIGS. 9A to 9I are views for explaining examples of a stretching stress applied to a display device when a display device according to exemplary embodiments of the present disclosure is stretched In the meantime, in FIG. 8, a pattern layer 120_C according to a comparative embodiment of the present disclosure and the pattern layers 120, 120_1, 120_2, 120_3, 120_4, 120_5, 120_6, and 120_7 according to the exemplary embodiments of the present disclosure are stretched (for example, when a tension along the second direction Y is applied to the pattern layer). At this time, in the first to sixth positions P1, P2, P3, P4, P5, and P6 in which the third line patterns 123_C, 123L, 123L_1, 123L_2, 123L_3, 123L_4, 123L_5, 123L_6, and 123L_7 of the pattern layers 120_C, 120, 120_1, 120_2, 120_3, 120_4, 120_5, 120_6, and 120_7 are disposed, a maximum stretching stress (in FIG. 8, denoted as “PI max strain”) for the third line patterns 123_C, 123L, 123L_1, 123L_2, 123L_3, 123L_4, 123L_5, 123L_6, and 123L_7 is illustrated.

Further, in FIG. 9A, a stretching stress (denoted as “STR”) applied in every position of the pattern layer 120_C when the pattern layer 120_C according to the comparative embodiment of the present disclosure is stretched is illustrated. In FIGS. 9A to 9I, a stretching stress (denoted by “STR”) applied in every position of the pattern layers 120, 120_1, 120_2, 120_3, 120_4, 120_5, 120_6, and 120_7 when the pattern layers 120, 120_1, 120_2, 120_3, 120_4, 120_5, 120_6, and 120_7 according to the exemplary embodiments of the present disclosure described with reference to FIGS. 6A to 6H are stretched is illustrated.

First, referring to FIGS. 8 and 9A together, unlike the exemplary embodiment which has been described with reference to FIGS. 5 to 6H, a plurality of third plate patterns 123P_C included in the pattern layer 120_C according to the comparative embodiment of the present disclosure do not have different sizes along the second direction Y. Further, the plurality of third line patterns 123L_C does not include a 3-2-th line pattern 123L2 having a second length ratio.

When the pattern layer 120_C according to the comparative embodiment of the present disclosure as described above is stretched, as illustrated in FIGS. 8 and 9A, in the first to sixth positions P1, P2, P3, P4, P5, and P6 in which the third line pattern 123L_C is disposed, a maximum stretching stress having a relatively large deviation is obtained. That is, when the pattern layer 120_C according to the comparative embodiment of the present disclosure is stretched, the stretching stress is not dispersed in the first to sixth positions P1, P2, P3, P4, P5, and P6 in which the third line pattern 123L_C is disposed, but the stretching stress is concentrated in a portion adjacent to the bonding area BDA. Therefore, crack or damage may occur in the pattern layer 120 of the display device 100.

In contrast, referring to FIGS. 8 and 9B to 9I, as illustrated in 9B, 9D to 9I, when the plurality of third plate patterns 123P, 123P_2, 123P_3, 123P_4, 123P_5, 123P_6, and 123P_7 has different sizes along the second direction Y and/or as illustrated in FIGS. 9C to 9E, and 9I, the plurality of third line patterns 123L_1, 123L_2, 123L_3, and 123L_7 includes not only a 3-1-th line pattern 123L1 having a first length ratio, but also a 3-2-th line pattern 123L2 having a second length ratio for suppressing the excessive stretching, if the pattern layers 120, 120_1, 120_2, 120_3, 120_4, 120_5, 120_6, and 120_7 are stretched, as illustrated in FIG. 8, in the first to sixth positions P1, P2, P3, P4, P5, and P6 in which the third line patterns 123L, 123L_1, 123L_2, 123L_3, 123L_4, 123L_5, 123L_6, and 123L_7 are disposed, a maximum stretching stress having a relatively small deviation may be obtained. That is, in the case of the pattern layers 120, 120_1, 120_2, 120_3, 120_4, 120_5, 120_6, and 120_7 according to the exemplary embodiments of the present disclosure, in the first to sixth positions P1, P2, P3, P4, P5, and P6 in which the third line patterns 123L, 123L_1, 123L_2, 123L_3, 123L_4, 123L_5, 123L_6, and 123L_7 are disposed, the stretching stress may be dispersed. Accordingly, the damage or crack of the third line patterns 123L, 123L_1, 123L_2, 123L_3, 123L_4, 123L_5, 123L_6, and 123L_7 included in the display device 100 may be suppressed.

FIG. 10 is a view for explaining an example of a link line included in a display device of FIG. 5.

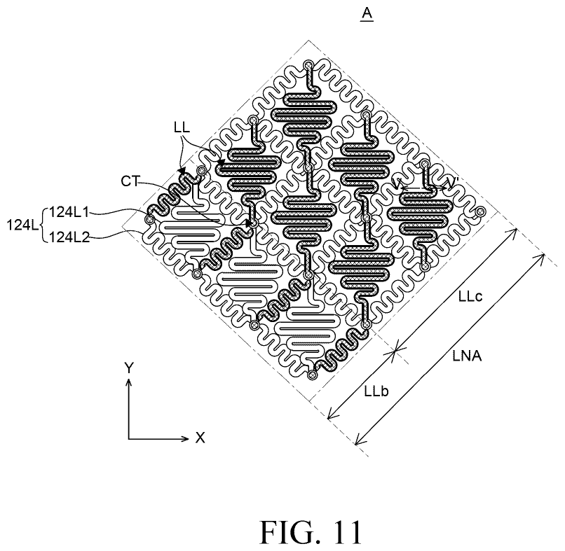

FIG. 11 is an enlarged plan view illustrating an example of a part A of FIG. 10.

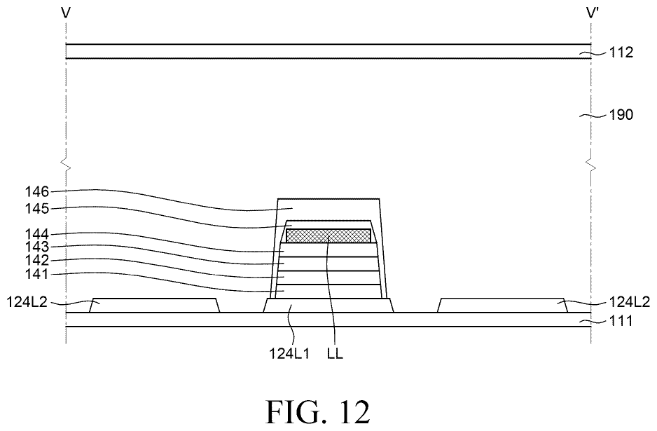

FIG. 12 is a cross-sectional view illustrating an example taken along the line V-V′ of FIG. 11.

Referring to FIGS. 5 and 10, the plurality of link lines LL may be disposed on the bonding area BDA, the island area ISA, and the link line area LNA.

One end of each of the plurality of link lines LL is connected to the plurality of pads of the flexible films 130 in the bonding area BDA to transmit various signals from the printed circuit board PCB and the flexible film 130 to the active area AA. For example, each of the plurality of link lines LL may transmit a data voltage or a reference voltage to the plurality of wiring lines of the active area AA.

Each of the plurality of link lines LL may include a first line portion LLa, a second line portion LLb, and a third line portion LLc. The first line portion LLa is disposed on the island area ISA and one end thereof is connected to the plurality of pads of the bonding area BDA. The second line portion LLb is disposed on a partial area of the link line area LNA which is in contact with the island area ISA as a partial area of the link line area LNA and one end thereof is connected to the other end of the first line portion LLa. The third line portion LLc is disposed on an area excluding an area in which the second line portion LLb is disposed as a remaining area of the link line area LNA and an end thereof is connected to the other end of the second line portion LLb.

For example, the first line portion LLa of each of the plurality of link lines LL may be disposed on the plurality of third plate patterns 123P, 123P_1, 123P_2, 123P_3, 123P_4, 123P_5, 123P_6, and 123P_7 and the plurality of third line patterns 123L, 123L_1, 123L_2, 123L_3, 123L_4, 123L_5, 123L_6, and 123L_7, as described with reference to FIGS. 6A to 6H.

Further, the second line portion LLb of each of the plurality of link lines LL extends from the first line portion LLa (or is connected to the first line portion LLa) to entirely extend along the second direction Y. Further, the third line portion LLc of each of the plurality of link lines LL extends from the second line portion LLb (or is connected to the second line portion LLb) to entirely extend in a diagonal direction between the first direction X and the second direction Y.

To be more specific, further referring to FIG. 11, the pattern layer 120 may further include a fourth line pattern 124L disposed on the link line area LNA. The fourth line pattern 124L may be connected to the third plate pattern 123P disposed in the island area ISA. For example, the fourth line pattern 124L may be connected to the 3-4-th plate pattern 123P4 which is the most adjacent to the link line area LNA, among the third plate patterns 123P disposed in the island area ISA.

The fourth line pattern 124L may include a plurality of 4-1-th line patterns 124L1 and a plurality of 4-2-th line patterns 124L2.

Each of the plurality of 4-1-th line patterns 124L1 extends in the second direction Y and may have a third shape. For example, each of the plurality of 4-1-th line patterns 124L1 may have a wavy shape (for example, a sine wave shape). However, the present disclosure is not limited thereto and each of the plurality of 4-1-th line patterns 124L1 extends in a zigzag pattern or may be formed with various shapes such as a shape extended by connecting a plurality of rhombus-shaped substrates at vertexes or a shape in which semicircular or quadrant shaped substrates are connected to each other.

Further, the plurality of 4-2-th line patterns 124L2 may be disposed so as to surround the plurality of 4-1-th line patterns 124L1. For example, some of the plurality of 4-2-th line patterns 124L2 is disposed so as to extend in a diagonal direction between the first direction X and the second direction Y and the others of the plurality of 4-2-th line patterns 124L2 may be disposed so as to extend in a different direction (for example, a vertical direction) from the diagonal direction. For example, two 4-2-th line pattern 124L2 extending in the diagonal direction and two 4-2-th line patterns 124L2 extending in a vertical direction of the diagonal direction, among the plurality of 4-2-th line patterns 124L2, are formed in a rhombus shape. Further, one 4-1-th line pattern 124L1 may be disposed in four 4-2-th line patterns 124L2 which are disposed in a rhombus shape.

Each of the plurality of 4-2-th line patterns 124L2 may have a fourth shape. For example, each of the plurality of 4-2-th line patterns 124L2 may have a wavy shape (for example, a sine wave shape). However, the present disclosure is not limited thereto and each of the plurality of 4-2-th line patterns 124L2 extends in a zigzag pattern or may be formed with various shapes such as a shape extended by connecting a plurality of rhombus-shaped substrates at vertexes or a shape in which semicircular or quadrant shaped substrates are connected to each other.

In one exemplary embodiment, each of the plurality of 4-1-th line patterns 124L1 has a third length ratio and each of the plurality of 4-2-th line patterns 124L2 may have a fourth length ratio which is smaller than the third length ratio.

For example, the fourth length ratio of each of the plurality of 4-2-th line patterns 124L2 may be designed to have a minimum length ratio in consideration of a line width (critical dimension) of the plurality of link lines LL disposed on the plurality of 4-2-th line patterns 124L2. The third length ratio of each of the plurality of 4-1-th line patterns 124L1 may be larger than the fourth length ratio. As described above, the plurality of fourth line patterns 124L disposed on the link line area LNA, that is, the plurality of 4-1-th line patterns 124L1 and the plurality of 4-2-th line patterns 124L2 are designed to have different length ratios to enhance the durability for stretching of the display device 100.

In one exemplary embodiment, the plurality of fourth line patterns 124L, for example, the plurality of 4-1-th line patterns 124L1 and the plurality of 4-2-th line patterns 124L2 may be rigid patterns. For example, the plurality of 4-1-th line patterns 124L1 and the plurality of 4-2-th line patterns 124L2 may be more rigid than the lower substrate 111 and the upper substrate 112.

The plurality of 4-1-th line patterns 124L1 and the plurality of 4-2-th line patterns 124L2 which are rigid substrates may be formed of a plastic material having flexibility lower than that of the lower substrate 111 and the upper substrate 112. For example, the plurality of 4-1-th line patterns 124L1 and the plurality of 4-2-th line patterns 124L2 may include at least one of polyimide (PI), polyacrylate, and polyacetate. According to the exemplary embodiment, the plurality of 4-1-th line patterns 124L1 and the plurality of 4-2-th line patterns 124L2 may include the same material. At this time, when the plurality of 4-1-th line patterns 124L1 and the plurality of 4-2-th line patterns 124L2 include the same material, the plurality of 4-1-th line patterns 124L1 and the plurality of 4-2-th line patterns 124L2 may be integrally formed. For example, one end and the other end of each of the plurality of 4-1-th line patterns 124L1 are connected at two vertices which are opposite in the second direction Y, among rhombus vertices formed by four 4-2-th line patterns 124L2 to be integrally formed. For example, the 4-1-th line pattern 124L1 and the 4-2-th line pattern 124L2 may be connected by a contact unit CT.

Moduli of elasticity of the plurality of fourth line patterns 124L, for example, the plurality of 4-1-th line patterns 124L1 and the plurality of 4-2-th line patterns 124L2 may be higher than moduli of elasticity of the lower substrate 111 and the upper substrate 112. For example, moduli of elasticity of the plurality of 4-1-th line patterns 124L1 and the plurality of 4-2-th line patterns 124L2 may be 1000 times higher than the moduli of elasticity of the lower substrate 111 and the upper substrate 112, but the exemplary embodiment of the present disclosure is not limited thereto.

The plurality of link lines LL may be disposed on the fourth line pattern 124L. For example, the second line portion LLb of each of the plurality of link lines LL is disposed on the plurality of 4-1-th line patterns 124L1 and the third line portion LLc of each of the plurality of link lines LL may be disposed on the plurality of 4-2-th line patterns 124L2. As described above, the plurality of link lines LL is disposed on the 4-1-th line pattern 124L1 and the 4-2-th line pattern 124L2 having stretchability to be freely extended or bended. Therefore, the second non-active area NA2, for example, the link line area LNA has a stretchability together with the active area AA to be flexibly deformed.

Further, in the link line area LNA, the plurality of fourth line patterns 124L may also be disposed in a part in which the plurality of link lines LL is not disposed. For example, in an area of the link line area LNA in which the second line portion LLb of the plurality of link lines LL is disposed, the link line LL is disposed only in the 4-1-th line pattern 124L1, but the link line LL is not disposed on the 4-2-th line pattern 124L2. In an area of the link line area LNA in which the third line portion LLc of the plurality of link lines LL is disposed, the link line LL is disposed only in the 4-2-th line pattern 124L2, but the link line LL is not disposed on the 4-1-th line pattern 124L1. As described above, also in the area in which the plurality of link lines LL is not disposed, the plurality of fourth line patterns 124L which is rigid patterns is disposed so that the durability for the stretching of the display device 100 may be enhanced.

In order to describe the cross-sectional structure of the link line area LNA, further referring to FIG. 12, in an area of the link line area LNA in which the second line portion LLb of the link line LL is disposed, a plurality of insulating layers is disposed on the 4-1-th line pattern 124L1 and the plurality of link lines LL may be disposed above any one of the plurality of insulating layers.

For example, a buffer layer 141, a gate insulating layer 142, a first interlayer insulating layer 143, and a second interlayer insulating layer 144 are disposed on the 4-1-th line pattern 124L1 and the plurality of link lines LL may be disposed on the second interlayer insulating layer 144. Further, the passivation layer 145 and the planarization layer 146 are disposed on the plurality of link lines LL to protect the link line LL.

In the meantime, in FIG. 12, only a cross-sectional structure of an area of the link line area LNA in which the second line portion LLb of the link line LL is disposed is illustrated. However, in the area of the link line area LNA in which the third line portion LLc of the link line LL is disposed, the plurality of insulating layers is disposed on the 4-2-th line pattern 124L2 and the plurality of link lines LL may be disposed above any one of the plurality of insulating layers.

As described above, in the display device according to the exemplary embodiments of the present disclosure, in a non-active area disposed on one side of the active area, a size (or an area) of a plate pattern bonded to the flexible film may be gradually reduced toward the active area from the flexible film. Accordingly, when the display device is stretched, a stretching stress of a line pattern which connects adjacent plate patterns in the non-active area and a link line disposed on the line pattern may be effectively dispersed. Therefore, the damage or crack of the pattern layer included in the display device may be suppressed.

Further, in the case of the display device according to the exemplary embodiments of the present disclosure, a length ratio of a line pattern connected to the plate pattern which is bonded to the flexible film in the non-active area may have a different value in every line pattern. Accordingly, the over-stretching of the non-active area when the display device is stretched may be suppressed and the damage or the crack of the pattern layer included in the display device may be suppressed.

The exemplary embodiments of the present disclosure can also be described as follows:

According to an aspect of the present disclosure, a display device includes a lower substrate including an active area, a first non-active area on both sides of the active area along a first direction, and a second non-active area on one side of the active area along a second direction which is different from the first direction, a plurality of plate patterns in the active area, the first non-active area, and the second non-active area, and a plurality of line patterns between the plurality of plate patterns in the active area, the first non-active area, and the second non-active area and the plurality of plate patterns disposed in the second non-active area has a different size.

The more adjacent to the active area, the smaller the size of the plurality of plate patterns disposed in the second non-active area.

The plurality of plate patterns may include a plurality of first plate patterns in the active area and spaced apart from each other, a plurality of second plate patterns in the first non-active area and spaced apart from each other and a plurality of third plate patterns in the second non-active area and spaced apart from each other. The plurality of line patterns includes a plurality of first line patterns between the plurality of first plate patterns, a plurality of second line patterns between the plurality of second plate patterns and a plurality of third line patterns between the plurality of third plate patterns.

The plurality of third plate patterns may include a 3-1-th plate pattern, a 3-2-th plate pattern, a 3-3-th plate pattern, and a 3-4-th plate pattern which are sequentially disposed along an opposite direction of the second direction.

A first size of the 3-1-th plate pattern may be larger than a second size of the 3-2-th plate pattern, the second size of the 3-2-th plate pattern may be larger than a third size of the 3-3-th plate pattern, and the third size of the 3-3-th plate pattern may be larger than a fourth size of the 3-4-th plate pattern.

Widths of the 3-1-th plate pattern, the 3-2-th plate pattern, the 3-3-th plate pattern, and the 3-4-th plate pattern in the first direction may be reduced toward an opposite direction of the second direction.

Widths of the 3-1-th plate pattern, the 3-2-th plate pattern, the 3-3-th plate pattern, and the 3-4-th plate pattern may be the same in the second direction.

The number of the 3-1-th plate patterns, the 3-2-th plate patterns, the 3-3-th plate patterns, and the 3-4-th plate patterns per unit area may be increased toward an opposite direction of the second direction.

The plurality of third line patterns may be disposed between third plate patterns which are adjacent in the second direction, among the plurality of third plate patterns, to connect the third plate patterns adjacent in the second direction.

The plurality of third line patterns may include a 3-1-th line pattern having a first shape and a 3-2-th line pattern having a second shape which is different from the first shape.

A first length ratio of the 3-1-th line pattern may be larger than a second length ratio of the 3-2-th line pattern and the length ratio may be defined by a ratio of a length in a non-stretched state and a length in a maximum stretched state.

The 3-2-th line pattern may be disposed between 3-1-th line patterns which are adjacent in the first direction.

The plurality of third plate patterns may include 3-1-th plate pattern, a 3-2-th plate pattern, and a 3-4-th plate pattern which are sequentially disposed along an opposite direction of the second direction.

A first size of the 3-1-th plate pattern is larger than a second size of the 3-2-th plate pattern, and the second size of the 3-2-th plate pattern is larger than a fourth size of the 3-4-th plate pattern.

Widths of the 3-1-th plate pattern, the 3-2-th plate pattern, and the 3-4-th plate pattern in the first direction are reduced toward an opposite direction of the second direction.

Widths of the 3-1-th plate pattern, the 3-2-th plate pattern, and the 3-4-th plate pattern are the same in the second direction.

The plurality of third plate patterns may include a 3-1-th plate pattern, a 3-5-th plate pattern, and a 3-4-th plate pattern which are sequentially disposed along an opposite direction of the second direction.

Each of a width of the 3-5-th plate pattern in the first direction and a width of the 3-4-th plate pattern in the first direction is less than a width of the 3-1-th plate pattern in the first direction, and a width of the 3-5-th plate pattern and a width of the 3-4-th plate pattern in the first direction are same.

A width of the 3-5-th plate pattern in the second direction is greater than a width of the 3-4-th plate pattern in the second direction.

According to another aspect of the present disclosure, a display device include a lower substrate including an active area, a first non-active area on both sides of the active area along a first direction, and a second non-active area on one side of the active area along a second direction which is different from the first direction, a plurality of plate patterns in the active area, the first non-active area, and the second non-active area, a plurality of line patterns between the plurality of plate patterns in the active area, the first non-active area, and the second non-active area, and a plurality of link lines on the plurality of line patterns in the second non-active area.

The plurality of plate patterns may include a plurality of first plate patterns in the active area and spaced apart from each other, a plurality of second plate patterns in the first non-active area and spaced apart from each other and a plurality of third plate patterns in the second non-active area and spaced apart from each other. The plurality of line patterns may include a plurality of first line patterns between the plurality of first plate patterns, a plurality of second line patterns between the plurality of second plate patterns, a plurality of third line patterns between the plurality of third plate patterns and a plurality of fourth line patterns connected to the plurality of third plate patterns.

The second non-active area may include an island area in which the plurality of third plate patterns and the plurality of third line patterns are disposed and a link line area in which the plurality of fourth line patterns are disposed and disposed between the island area and the active area.

The plurality of fourth line patterns may include a plurality of 4-1-th line patterns which extends in the second direction and has a third shape and a plurality of 4-2-th line patterns which is disposed so as to surround the plurality of 4-1-th line patterns and has a fourth shape different from the third shape.

Some of the plurality of 4-2-th line patterns may extend in a diagonal direction between the first direction and the second direction and the others of the plurality of 4-2-th line patterns may extend in a vertical direction to the diagonal direction.

A third length ratio of the 4-1-th line pattern may be larger than a fourth length ratio of the 4-2-th line pattern and the length ratio may be defined by a ratio of a length in a non-stretched state and a length in a maximum stretched state.

The plurality of link lines may include a first line portion on the plurality of third plate patterns and the plurality of third line patterns in the island area, a second line portion on the plurality of 4-1-th line patterns in an area of the link line area which is in contact with the island area and a third line portion on the plurality of 4-2-th line patterns in an area of the link line area excluding an area in which the second line portion is disposed.

Additional embodiments of the present disclosure are described below.

For example, in some embodiments, a display device 100 may include a substrate 111 having an active area AA, a first non-active area NA1 disposed on both lateral sides of the active area along a first direction X, and a second non-active area NA2 disposed adjacent to one side of the active area along a second direction Y that is transverse to the first direction. A plurality of plate patterns 121P, 122P, 123P are disposed in the active area AA, the first non-active area NA1, and the second non-active area NA2. A plurality of line patterns 121L, 122L, 123L extend between adjacent plate patterns of the plurality of plate patterns. In the non-active areas NA1 and NA2, the plate patterns are formed with sizes that vary with position relative to the active area AA, such that plate patterns nearer to the active area have different dimensions compared to those farther away (see FIGS. 1 and 2).

In some embodiments, the plate patterns 123P disposed in the second non-active area NA2 vary in size with position relative to the active area AA. In particular, plate patterns closer to the active area, such as the plate pattern 123P4, are formed with smaller sizes than plate patterns farther from the active area, such as plate pattern 123P1 positioned nearer to the bonding area BDA of the flexible film 130. Thus, in plan view, the plate patterns decrease in size progressively toward the active area AA, providing an arrangement that gradually transitions from larger plate patterns adjacent to the bonding area to smaller plate patterns proximate the active area (see FIG. 6A).

In some embodiments, in cross-sectional view, the plate patterns 121P are disposed above the substrate 111 and are spaced apart from one another. Line patterns 121L are also disposed above the substrate 111 and extend between adjacent plate patterns. In this manner, the plate patterns and the line patterns form an island structure supported above the substrate, with the line patterns bridging the spacing between the plate patterns (see FIG. 4).

In some embodiments, a plurality of link lines may be disposed over the plate patterns and line patterns in the second non-active area NA2. The link lines extend toward the active area AA and provide electrical interconnection between the pads disposed on the flexible film 130 in the bonding area BDA and the pixels PX formed in the active area AA.

In some embodiments, the second non-active area NA2 defines a link line area LNA that is gradually widened or radially expanded toward the active area AA. The plurality of link lines disposed over the plate patterns and line patterns extend across this widening region, such that a pitch between adjacent link lines changes toward the active area. Accordingly, the arrangement of link lines provides a varying spacing in the direction toward the active area, consistent with the geometry of the widening link line area (see FIG. 10).

In some embodiments, the plate patterns 123P formed in the second non-active area NA2 have uniform widths in the first direction X, while exhibiting different lengths in the second direction Y. For example, the 3-1-th plate pattern 123P1, the 3-2-th plate pattern 123P2, the 3-3-th plate pattern 123P3, and the 3-4-th plate pattern 123P4 share a common dimension in the first direction X, yet their dimensions in the second direction Y differ, thereby providing plate patterns of varying length (see FIG. 6A).

In some embodiments, a flexible film 130 is bonded to the substrate 111 in a bonding area BDA. Plate patterns 123P positioned nearer to the bonding area of the flexible film, such as 123P1, are larger in size than plate patterns positioned nearer to the active area AA, such as 123P4. In this configuration, the plate patterns decrease in size in the direction from the flexible film 130 toward the active area AA, providing a graduated arrangement (see FIG. 5).

In some embodiments, the number of plate patterns per unit area increases toward the active area AA. For instance, in the portion of the second non-active area NA2 nearer the bonding area, relatively few large plate patterns (e.g., 123P1) are provided, whereas in the portion of the second non-active area nearer the active area AA, a greater number of smaller plate patterns (e.g., 123P4) are arranged. Thus, the density of plate patterns per unit area increases in the direction toward the active area (see FIG. 6A).

As shown in FIGS. 6B, 7A, and 7B, the line patterns 123L formed in the second non-active area NA2 include at least two groups of line patterns having different geometrical shapes when viewed in plan. For example, a first group of line patterns may have a first wavy configuration, while a second group of line patterns may be arranged in a different geometric configuration.

As depicted in FIGS. 7A and 7B, one group of line patterns has a wavy shape in plan view, while another group of line patterns has a zigzag shape in plan view. These differently-shaped line patterns may be disposed within the second non-active area NA2 to provide differentiated stretchability characteristics.

In some embodiments, as described with reference to FIG. 6A-6C, the line patterns formed in the non-active areas are configured with different length ratios from one another. By providing different length ratios, stretching stress applied to the non-active area is dispersed, and cracking of the pattern layer is suppressed. In this manner, the varying line patterns enhance the mechanical durability of the display device under bending or stretching.

In some embodiments, as further illustrated in FIGS. 7A and 7B, the line patterns are configured with length ratios selected to control stretching of the non-active area. By tailoring the length ratios of the line patterns, the stretching characteristics of the non-active areas can be adjusted, thereby controlling the degree of elongation under applied stress and minimizing damage to the pattern layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including an active area, a first non-active area on both sides of the active area along a first direction, and a second non-active area on one side of the active area along a second direction which is different from the first direction;
a plurality of plate patterns in the active area, the first non-active area, and the second non-active area; and
a plurality of line patterns between the plurality of plate patterns in the active area, the first non-active area, and the second non-active area,
wherein the plurality of plate patterns disposed in the second non-active area have sizes that are different from one another.

2. The display device according to claim 1, wherein the plurality of plate patterns disposed in the second non-active area are smaller in size when positioned closer to the active area than when positioned farther from the active area.

3. The display device according to claim 1, wherein the plurality of plate patterns includes:
a plurality of first plate patterns in the active area and spaced apart from each other;
a plurality of second plate patterns in the first non-active area and spaced apart from each other; and
a plurality of third plate patterns in the second non-active area and spaced apart from each other, and
wherein the plurality of line patterns includes:
a plurality of first line patterns between the plurality of first plate patterns;
a plurality of second line patterns between the plurality of second plate patterns; and
a plurality of third line patterns between the plurality of third plate patterns.

4. The display device according to claim 3, wherein the plurality of third plate patterns includes a 3-1-th plate pattern, a 3-2-th plate pattern, a 3-3-th plate pattern, and a 3-4-th plate pattern which are sequentially disposed along an opposite direction of the second direction.

5. The display device according to claim 4, wherein a first size of the 3-1-th plate pattern is larger than a second size of the 3-2-th plate pattern, the second size of the 3-2-th plate pattern is larger than a third size of the 3-3-th plate pattern, and the third size of the 3-3-th plate pattern is larger than a fourth size of the 3-4-th plate pattern.

6. The display device according to claim 5, wherein widths of the 3-1-th plate pattern, the 3-2-th plate pattern, the 3-3-th plate pattern, and the 3-4-th plate pattern in the first direction are reduced toward an opposite direction of the second direction.

7. The display device according to claim 5, wherein widths of the 3-1-th plate pattern, the 3-2-th plate pattern, the 3-3-th plate pattern, and the 3-4-th plate pattern are the same in the second direction.

8. The display device according to claim 4, wherein the number of the 3-1-th plate patterns, the 3-2-th plate patterns, the 3-3-th plate patterns, and the 3-4-th plate patterns per unit area increases toward the active area along the second direction.

9. The display device according to claim 3, wherein the plurality of third line patterns is disposed between adjacent third plate patterns in the second direction, among the plurality of third plate patterns, to connect the adjacent third plate patterns.

10. The display device according to claim 3, wherein the plurality of third line patterns includes:
a 3-1-th line pattern having a first shape; and
a 3-2-th line pattern having a second shape which is different from the first shape.

11. The display device according to claim 10, wherein a first length ratio of the 3-1-th line pattern is larger than a second length ratio of the 3-2-th line pattern, and
wherein the length ratio is defined as a ratio of a curved length of the line pattern in a non-stretched state to a straightened length of the line pattern in a maximum stretched state.

12. The display device according to claim 10, wherein the 3-2-th line pattern is disposed between 3-1-th line patterns which are adjacent in the first direction.

13. The display device according to claim 3, wherein the plurality of third plate patterns includes a 3-1-th plate pattern, a 3-2-th plate pattern, and a 3-4-th plate pattern which are sequentially disposed along an opposite direction of the second direction.

14. The display device according to claim 13, wherein a first size of the 3-1-th plate pattern is larger than a second size of the 3-2-th plate pattern, and the second size of the 3-2-th plate pattern is larger than a fourth size of the 3-4-th plate pattern.

15. The display device according to claim 14, wherein widths of the 3-1-th plate pattern, the 3-2-th plate pattern, and the 3-4-th plate pattern in the first direction are reduced toward an opposite direction of the second direction.

16. The display device according to claim 14, wherein widths of the 3-1-th plate pattern, the 3-2-th plate pattern, and the 3-4-th plate pattern are the same in the second direction.

17. The display device according to claim 3, wherein the plurality of third plate patterns includes a 3-1-th plate pattern, a 3-5-th plate pattern, and a 3-4-th plate pattern which are sequentially disposed along an opposite direction of the second direction.

18. The display device according to claim 17, wherein each of a width of the 3-5-th plate pattern in the first direction and a width of the 3-4-th plate pattern in the first direction is less than a width of the 3-1-th plate pattern in the first direction, and a width of the 3-5-th plate pattern and a width of the 3-4-th plate pattern in the first direction are same.

19. The display device according to claim 18, wherein a width of the 3-5-th plate pattern in the second direction is greater than a width of the 3-4-th plate pattern in the second direction.

20. A display device, comprising:
a substrate including an active area, a first non-active area on both sides of the active area along a first direction, and a second non-active area on one side of the active area along a second direction which is different from the first direction;
a plurality of plate patterns in the active area, the first non-active area, and the second non-active area;
a plurality of line patterns between the plurality of plate patterns in the active area, the first non-active area, and the second non-active area; and
a plurality of link lines on the plurality of line patterns in the second non-active area.

21. The display device according to claim 20, wherein the plurality of plate patterns includes:
a plurality of first plate patterns in the active area and spaced apart from each other;
a plurality of second plate patterns in the first non-active area and spaced apart from each other; and
a plurality of third plate patterns in the second non-active area and spaced apart from each other, and
wherein the plurality of line patterns includes:
a plurality of first line patterns between the plurality of first plate patterns;
a plurality of second line patterns between the plurality of second plate patterns;
a plurality of third line patterns between the plurality of third plate patterns; and
a plurality of fourth line patterns connected to the plurality of third plate patterns.

22. The display device according to claim 21, wherein the second non-active area includes:
an island area in which the plurality of third plate patterns and the plurality of third line patterns are disposed; and
a link line area in which the plurality of fourth line patterns are disposed, the link line area being disposed between the island area and the active area.

23. The display device according to claim 22, wherein the plurality of fourth line patterns includes:
a plurality of 4-1-th line patterns which extend in the second direction and has a third shape; and
a plurality of 4-2-th line patterns which is disposed so as to surround the plurality of 4-1-th line patterns and has a fourth shape different from the third shape.

24. The display device according to claim 23, wherein some of the plurality of 4-2-th line patterns extend in a diagonal direction between the first direction and the second direction and the others of the plurality of 4-2-th line patterns extend in a vertical direction to the diagonal direction.

25. The display device according to claim 23, wherein a third length ratio of the 4-1-th line pattern is larger than a fourth length ratio of the 4-2-th line pattern, and
wherein the length ratio is defined as a ratio of a curved length of the line pattern in a non-stretched state to a straightened length of the line pattern in a maximum stretched state.

26. The display device according to claim 23, wherein the plurality of link lines includes:
a first line portion on the plurality of third plate patterns and the plurality of third line patterns in the island area;
a second line portion on the plurality of 4-1-th line patterns in an area of the link line area which is in contact with the island area; and
a third line portion on the plurality of 4-2-th line patterns in an area of the link line area excluding an area in which the second line portion is disposed.

27. A display device, comprising:
a substrate including an active area, a first non-active area disposed on both lateral sides of the active area in a first direction, and a second non-active area disposed adjacent to one side of the active area in a second direction transverse to the first direction;
a plurality of plate patterns disposed in the active area, the first non-active area, and the second non-active area; and
a plurality of line patterns extending between adjacent plate patterns of the plurality of plate patterns,
wherein the plate patterns disposed in the non-active area have sizes that vary with position relative to the active area.

28. The display device of claim 27, wherein, in plan view, the plate patterns in the second non-active area have sizes that vary with position relative to the active area, such that plate patterns closer to the active area have smaller sizes than plate patterns farther from the active area.

28. The display device of claim 27, wherein, in plan view, the plate patterns in the second non-active area decrease in size progressively toward the active area.

29. The display device of claim 27, wherein, in cross-sectional view, the plate patterns and the line patterns are located above the substrate and the plate patterns are spaced apart from one another with the line patterns extending between adjacent plate patterns.

30. The display device of claim 27, further comprising a plurality of link lines disposed over the plate patterns and the line patterns in the second non-active area, the link lines extending toward the active area.

31. The display device of claim 30, wherein the link lines are arranged so that a pitch between adjacent link lines changes toward the active area.

32. The display device of claim 27, wherein the plate patterns in the second non-active area have uniform widths in the first direction and different lengths in the second direction.

33. The display device of claim 27, further comprising a flexible film bonded to the substrate in a bonding area,
wherein the plate patterns positioned nearer to the bonding area of the flexible film are larger in size than plate patterns positioned nearer to the active area.

34. The display device of claim 27, wherein the number of plate patterns per unit area increases toward the active area.

35. The display device of claim 27, wherein the line patterns in the second non-active area includes at least two groups of line patterns having different geometrical shapes when viewed in plan.

36. The display device of claim 35, wherein one group of line patterns has a wavy shape in plan view and another group has a zigzag shape in plan view.

37. The display device of claim 27, wherein the line patterns in the non-active area have different length ratios from one another, such that stretching stress applied to the non-active area is dispersed and cracking of a pattern layer is suppressed.

38. The display device of claim 27, wherein the line patterns are configured with length ratios selected to control stretching of the non-active area.
